(19) United States
(12) Patent Application Publication
(10) Pub. No.: US 2010/0109016 A1
(43) Pub. Date: May 6, 2010

(54) POWER SEMICONDUCTOR MODULE

(75) Inventors: Yuji Yagi, Aichi (JP); Yasushi Yamada, Aichi (JP); Ikuo Nakagawa, Aichi (JP); Takashi Atsumi, Aichi (JP); Mikio Shirai, Aichi (JP); Ikuo Ohnuma, Miyagi (JP); Kiyohito Ishida, Miyagi (JP); Yoshikazu Takaku, Miyagi (JP)

Correspondence Address: SUGHRUE MION, PLLC, 2100 PENNSYLVANIA AVENUE, N.W., SUITE 800, WASHINGTON, DC, 20037, US

(73) Assignee: Toyota Jidosha Kabushiki Kaisha, Toyota-shi (JP)

(21) Appl. No.: 12/596,382

(22) PCT Filed: Apr. 17, 2008
(86) PCT No.: PCT/JP2008/057539

§ 371 Date: Jan. 7, 2010

(30) Foreign Application Priority Data
Apr. 17, 2007 (JP) 2007-108311

(51) Int. Cl. H01L 23/488; H01L 29/12

(52) U.S. Cl. 257/76; 257/750; 257/77; 257/779; 257/E29.068; 257/E23.023

(57) ABSTRACT

Provided is a power semiconductor module in which two components are bonded by a Bi based solder material. A Cu layer is provided on the surfaces thereof to be bonded by the Bi based solder material on the two-component. Two components, i.e., the components to be bonded, are a combination of a semiconductor element and an insulating part, or a combination of an insulating part and a radiator plate. The insulating part is composed of a Cu/SiNx/Cu laminated body.

### TECHNICAL FIELD

The present invention relates to a power semiconductor module.

### BACKGROUND ART

Usually, power semiconductor modules have a structure in which an insulator is provided to a power semiconductor so as to insulate the power semiconductor electrically from a current conducting section. This power semiconductor and the insulator are bonded to each other by a solder or the like.

Power semiconductor modules are each provided with a radiator plate in order to radiate heat generated from their semiconductor element effectively or dissipate the heat temporarily. This radiator plate and the insulator are bonded to each other by a solder. Accordingly, in general, in a power semiconductor modules, bonding with a solder is performed at two positions: a position between a semiconductor element and an insulator; and a position between an insulator and a radiator plate.

In power semiconductor modules, a large electric current flows into a power semiconductor element. Thus, a power loss (a steady loss and a switching loss) is generated, generating a large amount of heat and raising the temperature. Accordingly, a thermal cycling test is employed as a reliability test for power semiconductor modules.

In power semiconductor modules, solder bonding sections at the two positions are weakest; thus, deficiencies often generated when a thermal cycling test is employed are caused in the solder bonding sections at the two positions. Accordingly, in order to increase the operational lifetime of power semiconductor modules, it is important to suppress cracking of the solder bonding sections.

A power semiconductor module has at least two solder bonding sections. Thus, the melting points of the solder materials must be considered when selecting solder materials used at the two positions.

Specifically, if the temperature for the second soldering is higher than the melting point of the solder material used in the first soldering, the portion obtained by the first soldering will be melted at the time of the second soldering, resulting in misalignment or inclination of the bonded components, or other deficiencies. To avoid this problem, solder materials have been selected such that the melting point of the solder material used for the first soldering is higher than that of the solder material used for the second soldering.

So far, Pb based solder materials have been used at the two solder bonding sections. In particular, a Pb—Sn solder material is used and the ratio between Pb and Sn is varied, thereby changing the melting point within the range of about from 183 to 300° C. to attain the soldering at the two positions (see, for example, Non-Patent Document 1).

However, since Pb has toxicity, the use of Pb has declined, and the development of a Pb-free solder material has been desired.

Due to this desire for solder materials, Sn based solder materials having various compositions have been suggested.

However, the melting point of an Sn based soldering material may only be varied within a narrow range around 220° C. Thus, it is difficult to apply an Sn material to the first and second soldering processes.

Further, GaN or SiC, which are used for next-generation power semiconductor elements, have heat resistance at 200° C. or higher, and have a large dielectric breakdown electric field, saturated electron density, and the like, thus enabling the use of a high operating voltage and therefore high electric current. The magnitude of this current causes heat generated by the semiconductor element to increase to about 200° C., and as a result, the regions soldered with solder must also have resistance at 200° C. or higher.

However, the melting point of Sn based solder material is about 220° C. which means that the material is melted at this temperature. Moreover, the tensile strength thereof decreases remarkably at about 200° C. For this reason, for the next-generation power semiconductor elements which generate heat over 200° C., it is difficult to use an Sn based material is used as a bonding material in practice.

As a bonding material, a Ag based brazing material is generally known. However, the melting point thereof is as high as 650° C. or higher. At such a temperature, semiconductor elements are broken or denatured. Thus, the material may not be used for the present purpose.

Under such situations, it has been suggested that Bi be used as a solder material. As a simple substance, Bi has a melting point of 270° C., and is a bonding material with better heat resistance than Sn based solder material, which has a melting point of about 220° C.

In order to attain bonding at a desired bonding temperature, a Bi material containing Ag, Cu, Sb or Zn has been suggested as a solder material by which the solidus temperature and the liquidus temperature may be set to appropriate ranges (see, for example, Patent Document 1).

For example, a solder material including of three or more components, in which a metal element such as Ag which may be eutectic with respect to Bi, and Sn, Cu, In, Sb, Zn or another metal element are added to Bi has been suggested (see, for example, Patent Document 2).

In order to make the lifetime of the whole of a power semiconductor module long, it is important to improve the heat resistance or mechanical strength of each of its members.

Regarding an insulator of a power semiconductor module, a laminated body of Al/AlN/Al, in which an aluminum layer is provided as an electroconductive layer on each surface of an aluminum nitride ceramic (see, for example, Patent Document 2), has been proposed. This technique indicates that the lifetime of a power semiconductor module may be increased further by the use of the Al/AlN/Al laminated body compared to the use of a Cu/AlN/Cu laminated body, in which Cu layers are provided as electroconductive layers on an AlN ceramic.

A Cu/SiNx/Cu laminated body has been disclosed as an insulator, in which Cu is arranged as electroconductive layers on a silicon nitride ceramic (see, for example, Non-Patent Document 3). It is reported that when the Cu/SiNx/Cu laminated body is subjected to a thermal cycling test from −30 to 180° C., the SiN ceramic is not broken over 800 cycles.

However, according to this document, only the strength of the insulator is evaluated, and evaluation is not performed of a module in which the insulator is soldered to another member such as a power semiconductor or a radiator plate. Thus, no disclosure is provided regarding an effect of the Cu/SiNx/Cu laminated body on a solder bonding section, which is weakest in strength.

Patent Document 1: Japanese Patent Application Laid-Open (JP-A) No. 2005-72173

Patent Document 2: JP-A No. 2001-353590

Non-Patent Document 1: Yoichiro Baba “Dealing with HV Inverter Quality Maintenance”, Japan Welding Society, National Meeting, Lecture Summary, Chapter 77 (2005-9)

Non-Patent Document 2: Nagatomo et al., “Thermal Cycle Characteristic Analysis of Substrate for Power Module by a Finite Element Method”, the Journal of Japan Institute of Electronics Packaging, Vol. 3, No. 4, pp. 330 to 334, 2000

Non-Patent Document 3: L. Dupont, Z. Khatir, S. Lefebvre, S. Bontemps, “Effects of metallization thickness of ceramic substances on the reliability of power assemblies under high temperature cycling”, Microelectronics Reliability 46, pp. 1766 to 1771, 2006

### DISCLOSURE OF INVENTION

### Problems to be Solved by the Present Invention

An object of the present invention is to provide a power semiconductor module in which deficiencies such as cracking are not easily generated.

### Means for Solving Problems

The invention of claim 1 is a power semiconductor module including: a power semiconductor element having, on a surface thereof, a Cu layer; and an insulating part including a Cu/SiNx/Cu laminated body in which a SiNx ceramic plate is provided with Cu layers on both surfaces thereof, in which the power semiconductor element and the insulating part are arranged such that the Cu layer of the power semiconductor element and one of the Cu layers of the insulating part are opposed, and the two Cu layers are bonded to each other by a Bi based solder material.

The invention of claim 2 is a power semiconductor module including: a power semiconductor module including: a power semiconductor element; an insulating part including a Cu/SiNx/Cu laminated body in which a SiNx ceramic plate is provided with Cu layers on both surfaces thereof; and a radiator plate having a Cu layer on a surface thereof, in which the insulating part and the radiator plate are arranged such that one of the Cu layers of the insulating part and the Cu layer of the radiator plate are opposed, and the two Cu layers are bonded to each other by a Bi based solder material

As described above, the melting point of the Bi based solder material is about 270° C.; and thus, the Bi based solder material is a bonding substance having excellent heat resistance. However, when using Bi based solder material as a bonding material for a power semiconductor module, a new problem arises.

It has been newly discovered that when a power semiconductor module undergoes severe thermal cyclings, a remarkable reaction is caused at its bond interfaces in which an unnecessary reaction product is produced in accordance with the properties of the members that contact the Bi based solder material. This reaction product is harder or more brittle than the solder material present around the product, and therefore a crack may be generated from the position where this reaction product, or the reaction product may break to cause a crack.

This interfacial reaction becomes problem in particular in the case of GaN or SiC semiconductor elements, which are a focus of attention as next-generation semiconductor elements. In these next-generation semiconductor elements, the amount of heat generated is very large, and the temperature thereof may reach 200° C. or higher.

Thus, in the invention of claim 1 or claim 2, at interfaces at which a Bi based solder material contacts, Cu layers are provided. An unnecessary reaction product is not easily generated by Bi and Cu at the interface therebetween even when they are subjected to thermal cyclings. Thereby, a power semiconductor module may be produced in which deficiencies such as cracking are not easily generated.

Furthermore, a Cu/SiNx/Cu laminated body is used as the insulating part, in which both surface of SiNx are each provided with a Cu layer. In this laminated body, the Cu layers are arranged on both of the surfaces, respectively, and therefore, even when this laminated body is soldered with a Bi based solder material, an unnecessary reaction product is not easily generated by thermal cyclings.

The Cu/SiNx/Cu laminated body is less readily broken than a Cu/MN/Cu laminated body in a thermal cycling test. Moreover, the breaking strength of SiNx is higher than that of AlN. Accordingly, the lifetime of the insulating member itself increased. As a result, the reliability of the power semiconductor module may be increased.

Accordingly, according to claim 1 or claim 2, in which the Cu/SiNx/Cu laminated body is used as the insulating part, the module has a sufficient lifetime in thermal cyclings, in particular, thermal cyclings of from −40 to 200° C., wherein the difference between the temperatures is large.

The invention of claim 3 is the power semiconductor module according to claim 1 or 2, in which the difference between the coefficient of thermal expansion of the Cu/SiNx/Cu laminated body and that of the power semiconductor element is 1.6 ppm/° C. or lower before a thermal cycling test.

In the invention of claim 3, the difference between the coefficient of thermal expansion of the power semiconductor element and that of the insulating part is made small. Accordingly, it is possible to reduce warping of a solder bonding section caused by a difference in thermal expansion generated when the power semiconductor element and the insulating part are heated, and suppress the generation of cracks and the like.

Since a coefficient of thermal expansion is a value inherent to a material, it is generally thought that it is a constant value. However, earnest investigation by the inventors has indicated unexpectedly that the coefficient of thermal expansion after thermal cyclings becomes greater than the coefficient of thermal expansion before the thermal cyclings.

In other words, it has been discovered that when the coefficient of thermal expansion difference between the members to be bonded is adjusted and a power semiconductor module is designed on the supposition that the coefficient of thermal expansions of the members increase after thermal cyclings, the generation of a crack may be more effectively prevented in the solder bonding section.

As a result of further researches on the prevention of the generation of cracks in the solder bonding section, it has been discovered that when a Cu/SiNx/Cu laminated body is used as the insulating part, it is effective that the coefficient of thermal expansion difference between the power semiconductor element and the insulating part (Cu/SiNx/Cu laminated body) is set to 1.6 ppm/° C. before thermal cyclings.

The invention of claim 4 is the power semiconductor module according to any one of claims 1 to 3, in which the purity of Cu in the Cu/SiNx/Cu laminated body is 99.96% or more.

When Cu layers containing a large amount of impurity are used in the Cu/SiNx/Cu laminated body, the mechanical strength lowers and the lifetime of the Cu/SiNx/Cu laminated body might be reduced. Additionally, the coefficient of thermal expansion of the Cu/SiNx/Cu laminated body is also changed. Therefore, in order to prevent the solder bonding section from being cracked, it is appropriate to use Cu having a purity of 99.96% or more.

The Cu layers provided to the SiNx ceramic function as electroconductive layers. From this viewpoint also, it is preferable to use Cu containing few impurities.

The invention of claim 5 is the power semiconductor module according to claim 3 or 4, in which the coefficient of thermal expansion of the Cu/SiNx/Cu laminated body is adjusted by adjusting the thicknesses of the SiNx ceramic plate and the Cu layers.

The coefficient of thermal expansion of the Cu/SiNx/Cu laminated body may be adjusted by the addition of an impurity or another method. However, with this method, other physical properties of the laminated body may be affected, such as the electroconductivity or thermoconductivity thereof. It is therefore preferable to adjust the coefficient of thermal expansion of the Cu/SiNx/Cu laminated body by varying the thickness of each of the layers of the Cu/SiNx/Cu laminated body.

The invention of claim 6 is the power semiconductor module according to any one of claims 1 to 5, in which the Bi based solder material is (1) a pure Bi substance, (2) Bi—CuAlMn in which CuAlMn alloy particles are dispersed in Bi, (3) a material in which Cu is added to Bi, or (4) a material in which Ni is added to Bi.

As described above, in the interface between Bi and Cu, an unnecessary reaction product is not easily generated even by high-temperature heat generated from a semiconductor element, and further the melting point of Bi is high. Thus, as the Bi based solder material, (1) a pure Bi substance may be used. However, when the solder material is (2) Bi—CuAlMn in which CuAlMn alloy particles are dispersed in Bi, (3) a material in which Cu is added to Bi, or (4) a material in which Ni is added to Bi, brittleness inherent to Bi may be overcome and the mechanical strength may be increased.

The invention of claim 7 is the power semiconductor module according to claim 6, in which in the material in which Ni is added to Bi, the content of Ni is from 0.01% by mass to 7% by mass.

Considering the heating temperature at the time of the bonding, it is preferable to adjust the liquidus temperature and/or the solidus temperature of the solder material. The liquidus temperature or the solidus temperature may be adjusted by adding an additive or by another method. If Ni is added to Bi, the liquidus temperature increases as the addition amount thereof increases, as a result, a high temperature is required for melting the whole of the solder material.

When Ni is added to Bi, the brittleness peculiar to Bi may be overcome when the Ni content is 0.01% by mass or more, thereby, obtaining an effect of increasing the mechanical strength.

The addition of Ni causes a rise in the liquidus temperature so that the difference thereof from the solidus temperature increases. When the Ni content is 7% by mass or less, it is within a practical range even at the time of the bonding in the power semiconductor module. Moreover, with such a liquidus temperature, the semiconductor element is not broken even by heating at the time of the soldering.

The invention of claim 8 is the power semiconductor module according to claim 6, in which in the material in which Cu is added to Bi, the content of Cu is from 0.01% by mass to 5% by mass.

When Cu is added to Bi, the brittleness peculiar to Bi may be overcome when the Cu content is 0.01% by mass or more, thereby obtaining an effect of increasing mechanical strength.

The addition of Cu also causes a rise in the liquidus temperature, so that the difference thereof from the solidus temperature increases. When the Cu content is 5% by mass or less, it is within a practical range even at the time of the bonding in the power semiconductor module. Moreover, with such a liquidus temperature, the semiconductor element is not broken even by heating at the time of the soldering.

The invention of claim 9 is the power semiconductor module according to claim 6, in which in the Bi—CuAlMn, the content of the CuAlMn alloy particles is from 0.5% by mass to 20% by mass.

When the content of the CuAlMn alloy is 0.5% by mass or more and 20% by mass or less, the brittleness is overcome, resulting from the addition of a material exhibiting martensitic transformation properties. Furthermore, a sufficient bonding strength to the members to be bonded is obtained by a sufficient Bi content.

The invention of claim 10 is the power semiconductor module according to any one of claims 2 to 9, in which the power semiconductor element has a Ni layer on a surface thereof, the insulating part has a Ni layer on a surface thereof, the power semiconductor element and the insulating part are arranged such that the Ni layer of the power semiconductor element and the Ni layer of the insulating part are opposed, and the two Ni layers are bonded to each other by an alloy represented by Zn_{(1-x-y)}AlₓM_{y}, wherein x is from 0.02 to 0.10, y is from 0 to 0.02, and M represents a metal other than zinc and aluminum.

The power semiconductor module of claim 10 has at least (1) the power semiconductor element, (2) the insulating part, and (3) the radiator plate, in which bonding by soldering is attained at two positions, that is, the position between the power semiconductor element and the insulating part, and the position between the insulating part and the radiator plate. Hereinafter, a bonding section between the power semiconductor element and the insulating part is called a first bonding section, and a bonding section between the insulating part and the radiator plate is called a second bonding section.

In the soldering at the two positions, a step soldering technique is used. In the second soldering process, the whole including the regions soldered in the first soldering is heated; therefore, it is essential that the temperature for the second soldering is made sufficiently lower than the melting point of the solder material used in the first soldering so as not to cause the regions soldered in the first soldering to become misaligned or inclined. If the temperature for the second soldering is higher than the melting point of the solder material used in the first soldering, the regions soldered in the first soldering are melted at the time of the second soldering, generating a deficiency in that the soldered regions become misaligned or inclined.

In other words, if the melting point of the material for the second soldering is too high, it is required to select a material having a higher melting point than this as the material for the first soldering, and as a result, overall heating temperature increases, so that the workability decreases and production costs increase. Additionally, the power semiconductor element is also heated at the time of the solderings. Thus, to prevent the power semiconductor element from being broken or denatured, the upper limit of the heating temperature at the time of the solderings is 650° C., and is preferably about 450° C. In light of this, the melting point of the material for the second soldering is preferably as low as possible in order to allow flexibility in the selecting of the bonding material used for the first soldering.

As described above, however, in next-generation power semiconductor elements, heat to about 200° C. is generated, and it is therefore necessary that the melting point of the solder materials is higher than 200° C.

In other words, the melting point of the material for the second soldering is preferably as low as possible, but must be higher than 200° C.

Considering the process for producing power semiconductor modules as described above, the above-mentioned Bi based solder materials are very suitable as the material for the second soldering. Since the melting point of the Bi based solder materials is about 270° C., it is sufficient to select as the material for the first soldering, a solder material having a melting point in a temperature range that is sufficiently higher than 270° C. and is lower than the upper limit temperature of 650° C. of the soldering processes (more preferably 450° C.). As a result, the scope of materials that may be selected for the first soldering widens. Moreover, a solder material having a sufficiently higher melting point than 270° C. may be selected for the first soldering; therefore, in the second soldering process, the regions soldered in the first soldering neither become misaligned or inclined. Even when a large amount of heat generated by the semiconductor element raises the temperature of the module to about 200° C.; the bonding sections are heat resistant since the melting point of the Bi based solder material is about 270° C.

Additionally, in the invention of claim 10, the two Ni layers are bonded to each other by an alloy represented by Zn_{(1-x-y)}AlₓM_{y} where x is from 0.02 to 0.10, y is from 0 to 0.02, and M represents a metal other than zinc and aluminum.

The alloy represented by Zn_{(1-x-y)}AlₓM_{y} has a melting point of 382° C. Thus, even when the operation of the power semiconductor element generates heat such that the temperature reaches 200° C., deficiencies are not generated therein.

Furthermore, the alloy represented by Zn_{(1-x-y)}AlₓM_{y} is bonded to the Ni layers, and thereby a reaction product generated in the interfaces therebetween is not significantly increased even by thermal cyclings. As a result, the reaction product does not cause deficiencies, such as cracking or peeling, even as a result of temperature changes. Additionally, the bonding performance thereof is also excellent.

As described above, the upper limit of the soldering temperature is about 650° C., and preferably 450° C. The melting point of the alloy represented by Zn_{(1-x-y)}AlₓM_{y} is 382° C., and is lower than the upper temperature usable in the soldering processes. Thus, the semiconductor element is not broken by heating in the soldering processes.

Additionally, the melting point (382° C.) of the alloy represented by Zn_{(1-x-y)}AlₓM_{y} is higher than that of the Bi based solder material used for the second soldering (about 270° C.). Accordingly, when using the Bi based solder material for the second soldering, the alloy represented by Zn_{(1-x-y)}AlₓM_{y} is effective as a material for the first soldering.

The melting point (382° C.) of the alloy represented by Zn_{(1-x-y)}AlₓM_{y} is higher than that (about 270° C.) of the Bi based solder material. It is therefore preferable to use as solder material the alloy represented by Zn_{(1-x-y)}AlₓM_{y} in the first bonding section which is nearer to the semiconductor element which generates a large quantity of heat.

Therefore, according to the invention of claim 10, a highly reliable power semiconductor module may be obtained in which deficiencies such as cracking and peeling are not generated in thermal cyclings, and in which the components do not become misaligned or inclined in the production process thereof.

The invention of claim 11 is the power semiconductor module according to any one of claims 1 to 7, in which the power semiconductor element is composed of GaN or SiC.

A power semiconductor element in which GaN or SiC is used generates a larger quantity of heat than conventional power semiconductor elements. In the present invention, however, the Bi based solder material used in a bonding section has a solidus temperature of about 270° C.; thus, even when GaN or SiC, which are used in next-generation power semiconductor, are used, and the power semiconductor module is repeatedly used at a high temperature over 200° C., the present module is a highly reliable power semiconductor module in which deficiencies such as cracking and peeling are not caused in a bonding section.

The invention of claim 12 is the power semiconductor module according to any one of claims 2 to 11, in which the radiator plate is a laminated body including a Cu layer/Mo layer/Cu layer in which a Mo layer is provided with Cu layers on both surfaces thereof.

The Cu/Mo/Cu laminated body has a high thermoconductivity and effectively exhibits a function as a radiator plate. Moreover, the coefficient of thermal expansion of the Cu/Mo/Cu laminated body is about 4 ppm/K. The value is close to the coefficient of thermal expansion value of the power semiconductor element. As a result, a remarkable thermal stress is not generated through thermal cyclings, so that deficiencies such as cracking and peeling are not caused.

The Cu layers of this laminated body contact the above-mentioned Bi based solder material. In an interface between Bi and Cu, an unnecessary product is not generated even through thermal cyclings, and therefore, deficiencies such as cracking and peeling are not caused as a result of temperature change.

The invention of claim 13 is the power semiconductor module according to claim 12, in which the ratio by thickness in the radiator plate between the Cu layer, the Mo layer, and the Cu layer is from 1/5/1 to 1/12/1.

When the ratio between individual layers including Cu layer/Mo layer/Cu layer in the laminated body is from 1/5/1 to 1/2/1, a favorable balance may be attained between a thermoconductivity and a coefficient of thermal expansion, whereby the laminated body effectively exhibits a function as a radiator plate.

### EFFECTS OF INVENTION

According to the present invention, it is possible to provide a highly reliable power semiconductor module in which deficiencies such as cracking and peeling are not caused through thermal cyclings.

In particular, according to the present invention, it is possible to provide a power semiconductor module having a sufficient lifetime even under thermal cyclings having a large difference in temperature such as from −40 to 200° C.

### BRIEF DESCRIPTION OF DRAWINGS

FIG. 1 are a view illustrating the structure of a power semiconductor module 10 in a first exemplary embodiment: FIG. 1A is a plan view thereof and FIG. 1B is a sectional view thereof.

FIG. 2 is a graph showing an example of the relationship of the defective cycle number to the difference between the coefficient of thermal expansion of a Si semiconductor element and that of an insulating part.

FIG. 3 is a graph showing an example of the relationship between the thickness of the Cu layers in a Cu/SiNx/Cu laminated body and the coefficient of thermal expansion of the whole of the Cu/SiNx/Cu laminated body.

FIG. 4 is a view illustrating the structure of a power semiconductor module 10 in a second exemplary embodiment.

FIG. 5 is a view illustrating the structure of a power semiconductor module 10 in a fourth exemplary embodiment.

FIG. 6 is a view illustrating the structure of a power semiconductor module 10 in a fifth exemplary embodiment.

FIG. 7 is a view illustrating the structure of a power semiconductor module 10 in a sixth exemplary embodiment.

FIG. 8 is a sectional view illustrating the structure of an evaluating test body in Examples.

### BEST MODE FOR CARRYING OUT THE INVENTION

The power semiconductor module of the present invention has bonding sections whose faces to be bonded are provided with Cu layers, respectively, and the Cu layers are bonded to each other by a Bi based solder material. Combinations of members having the faces to be bonded are a combination of a power semiconductor element and an insulating part, or a combination of an insulating part and a radiator plate. The power semiconductor module of the present invention has at least one bonding section which is bonded by Bi based solder material, accordingly, may have two or more bonding sections which are bonded by Bi based solder material

First, the structure of the power semiconductor module will be described, and then each of constituting elements thereof will be described hereinafter.

<Power Semiconductor Module of First Exemplary Embodiment>

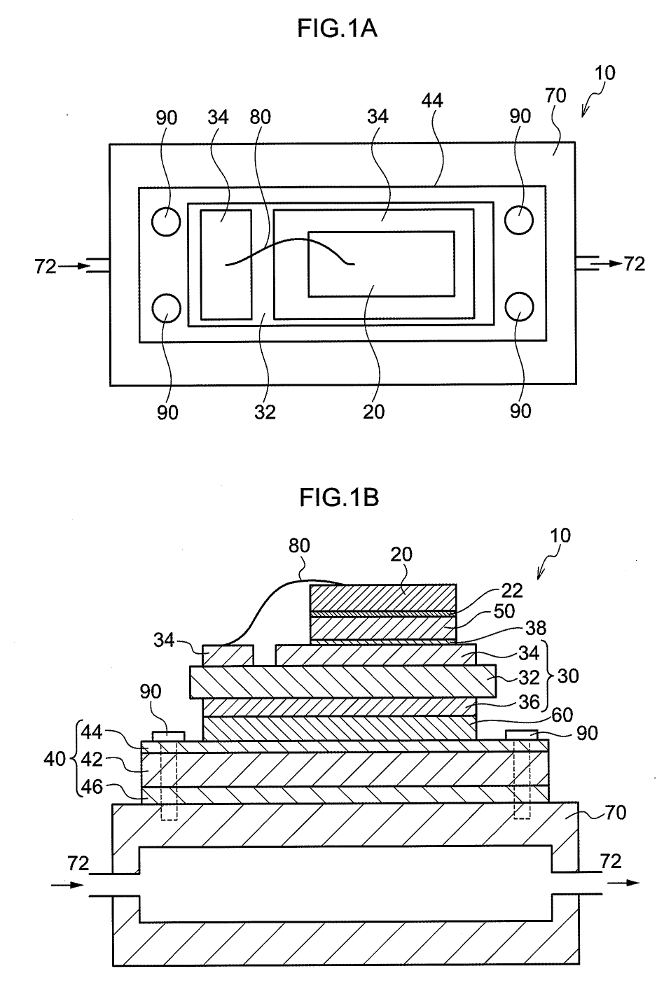

FIG. 1 schematically illustrate the structure of a power semiconductor module of a first exemplary embodiment. FIG. 1A is a plan view thereof, and FIG. 1B is a sectional view thereof.

A power semiconductor module 10 of the first exemplary embodiment has a power semiconductor element 20, an insulating part 30, and a radiator plate 40. The power semiconductor element 20 and the insulating part 30 are bonded to each other by a first bonding section 50. The insulating part 30 and the radiator plate 40 are bonded to each other by a second bonding section 60.

The power semiconductor module 10 is used as an inverter for vehicle use or the like. Around the power semiconductor module 10, an internal combustion engine, which does not illustrated in figure, is set up; thus, the environment in which the power semiconductor module 10 is placed becomes a considerably high temperature. Further, when GaN or SiC for the next-generation is used as the power semiconductor element, heat generated from the power semiconductor element 20 increases, whereby the temperature of the power semiconductor module 10 is raised.

In order to prevent the power semiconductor element from being broken by heat generated from the element itself or by high temperature of the surrounding environment, a cooler 70 in which a cooling water 72 flows is set, and the radiator plate 40 is located between the cooler 70 and the power semiconductor element 20. In FIG. 1, the radiator plate 40 is fixed to the cooler 70 with screws 90. However, the radiator plate 40 may be fixed to the cooler 70 by an adhesive or the like.

In general, therefore, a first performance required for a power semiconductor module is that deficiencies such as cracking and peeling are not generated therein through thermal cyclings. Second performances required are that electrical insulation is certainly attained by its insulating part, and third performances required are that heat generated from its power semiconductor element is conducted to its radiator plate, suppressing accumulation of heat.

In order not to crack or a peel through thermal cyclings, it is necessary that the members themselves such as a semiconductor element, an insulating part, an radiator plate, a bonding member and the like have durability even as a result of temperature changes. Additionally, it is important that the members do not cause the generation of an unnecessary reaction product through thermal cyclings. This reaction product is a brittle material or an excessively hard material; thus, cracking, peeling or the like is easily caused from the site where the reaction product is generated.

In order to suppress the generation of cracks, peels or the like through thermal cyclings, it is important that the coefficient of thermal expansions of the individual members are closed to each other. If members entirely different from each other in coefficient of thermal expansion are bonded to each other, cracking, peeling or the like is apt to be easily generated by a volume change of the members, which is repeatedly caused by thermal cyclings.

In the power semiconductor module as a bonded body according to the present invention, a Bi based solder material is used in the first bonding section 50 or the second bonding section 60; therefore, the heat resistance of the bonding section increases. Since the Cu layers are provided at the interfaces to be contacted with the Bi based solder material, an unnecessary reaction product is not produced at the interfaces to be contacted with Bi, even when the temperature thereof is raised by thermal cyclings. Thus, the generation of cracks, which results from the generation of the reaction product, may be suppressed.

Additionally, the Cu/SiNx/Cu laminated body is used as a insulating part; thus, the insulating member is also excellent durability even as a result of temperature change.

In the power semiconductor module of the present invention, it is allowable to use the Bi based solder material in any one of the first bonding section 50 and the second bonding section 60. It is also allowable to bond the first bonding section 50 in advance and then bond the second bonding section 60, or bond the second bonding section 60 in advance and then bond the first bonding section 50.

However, if the temperature for the second soldering is higher than the melting point of the solder material used for the first soldering, the portion soldered by the first soldering are melted during the second soldering, whereby deficiencies such as a misalignment or inclination of the bonded components may be caused.

In order to avoid this problem, solder materials are selected in such a manner that the melting point of the solder material used in the first soldering is higher than the melting point of the solder material used in the second soldering. It is preferable that the melting point of the solder material used for the second soldering is lower than the melting point of the solder material used for the first soldering by 30° C. or larger.

In other words, when a Bi based solder material is used for the first soldering, the solder material used for the second soldering is preferably a material having a lower melting point than that of the Bi based solder material by 30° C. or larger, since the melting point of Bi based solder material is 270° C. or higher. On the other hand, the melting point of the solder material for the second soldering is desirably 200° C. or higher, considering heat generated from the power semiconductor. Thus, when a Bi based solder material is used for the first soldering, it is preferable that the solder material used for the second soldering is a material having a melting point of about 210 to 240° C.

In the meantime, when a Bi based solder material is used for the second soldering, the solder material used for the first soldering is preferably a material having a solidus temperature of more than 30° C. higher than the melting point of the Bi based solder material. On the other hand, in order to prevent the semiconductor element form being broken by heating at the time of the soldering, the meting point thereof is preferably 650° C. or lower, and more preferably 450° C. or lower. Thus, when a Bi based solder material is used for the second bonding, it is preferable that the solder material used for the first bonding has a melting point of from 300 to 650° C., and preferably from 300 to 450° C.

From the above, it is preferable that a Bi based solder material is used for the second bonding since the melting point thereof is about 270° C. The solder material used for the first bonding is preferably a material having a sufficiently higher melting point than the melting point 270° C. of the Bi based solder material. However, in order to prevent the semiconductor element 20 form being broken by heating for the solderings in the production process, the melting point of the solder material used for the first bonding is preferably 650° C., and more preferably 450° C. or lower. In short, the solder material used for the first soldering preferably has a melting point of sufficiently higher than 270° C., and lower than 650° C. and more preferably 450° C.

Thus, the solder material used for the first soldering may be any one of alloy materials composed mainly of Zn. Of these materials, an alloy represented by Zn_{(1-x-y)}AlₓM_{y} (melting point: 382° C.) is preferable as a material used for the first soldering in order to prevent the power semiconductor element from being broken.

It is more preferable that an alloy represented by Zn_{(1-x-y)}AlₓM_{y}, which has a high melting point, is used in the first bonding section 50, which is on the side nearer to the semiconductor element which may generate a large amount of heat, and a Bi based solder material is used in the second bonding section 60, which is on the side farther from the semiconductor element.

Accordingly, in the first exemplary embodiment illustrated in FIG. 1, this case will be described, where an alloy represented by Zn_{(1-x-y)}AlₓM_{y} is used in the first bonding section 50 and a Bi based solder material is used in the second bonding section 60.

<Second Bonding Section>

The second bonding section 60 in the present invention is disposed to bond the insulating part 30 and the radiator plate 40 to each other. In the first exemplary embodiment illustrated in FIG. 1, a Bi based solder material is used for the second bonding section 60. In the present invention, the Bi based solder material is not particularly limited as far as the material is composed mainly of Bi. The “Bi based solder material” means a solder material containing 80% by mass or more of Bi.

Specifically, examples of the Bi based solder material include a pure Bi substance, and materials in which Cu, Ni or Ag is added to Bi. The Bi based solder material is preferably any one selected from Bi based solder materials described in items (1) to (4) described below so as not to lower the solidus temperature. For example, the solidus temperature of a material including 2.5% by mass of Ag in Bi drops to about 262° C. from 270° C. which is the solidus temperature of a pure Bi substance, therefore, this material is undesired, from the viewpoint of durability against heat generated by the operation of the semiconductor element.

Of the Bi based solder materials described in the items (1) to (4), Bi based solder materials in the items (2) to (4) are preferable in order to reduce the brittleness of Bi and enhance the mechanical strength.

(1) Pure Bi substance

(2) Bi—CuAlMn, in which CuAlMn alloy particles are dispersed in Bi

(3) Material in which Cu is added to Bi

(4) Material in which Ni is added to Bi

Each of the Bi based solder materials will be described in detail hereinafter.

(1) Pure Bi Substance

Bi is suitable as a solder material for a bonding section since Bi has a melting point around 270° C. However, it has been clear that the reaction becomes remarkable at the contacting interface to be contacted with Bi through severe thermal cyclings of from −40 to 200° C., depending on the kind of a material to be contacted with Bi, whereby an unnecessary reaction product is produced. This phenomenon has been unprecedentedly found out under a temperature condition of from −40 to 200° C.

When Bi is used as a solder material focusing having high heat resistance, the heat resistance of the solder is improved. However, in accordance with the state of the interface with the Bi based solder material, an unnecessary reaction product is produced through thermal cyclings, whereby cracks or the like cause. As a result, the heat resistance decreases.

Thus, in the present invention, an investigation was conducted on a material which does not generate an unnecessary product at the contacting interface even when the temperature of Bi is increased. Thus, Cu layers are provided at contacting interfaces with Bi. As a result, at the contacting interfaces with Bi, an unnecessary reaction product is not produced, whereby the generation of deficiencies such as cracking may be suppressed.

In other words, it's not that it suffices for improvement of the heat resistance of semiconductor module to apply Bi having a high melting point as a solder material in a bonding section. It requires consideration of combination of the kinds of a solder material and a material provided on interfaces to be contacted with the solder material.

(2) Bi—CuAlMn

Bi is suitable as a solder material for a second bond layer since Bi has a melting point of around 270° C. However, Bi is difficult to handle since Bi exhibits weak shearing force and brittleness. Consequently, the particles of a CuAlMn alloy are dispersed into Bi to increase strength. This function will be described in more detail.

A CuAlMn alloy may exhibit martensitic transformation properties. The alloy phase of metal exhibiting martensitic transformation properties will either be in a martensitic phase or a parent phase in accordance with temperature or pressure. When the alloy phase of the metal is in a martensitic phase, the metal is very flexible and the shape thereof may be changed by an external force, whereby stress caused by the external force may be alleviated. Since the shape thereof may change flexibly even when a thermal cycling is repeated, the accumulation of fatigue caused by stress is suppressed. When the alloy phase of the metal is in a parent phase, the metal undergoes phase transition to a martensitic phase due to an external force. Since the metal is elastically deformed, when the external force is removed, the metal may be restored into the original shape, which is memorized. As a result, stress applied to the metal can be alleviated and the accumulation of stress can be suppressed.

Accordingly, by adding a CuAlMn alloy, which has martensitic transformation properties, to Bi, which is a bulk metal, stress from an external force may be alleviated and the accumulation of stress may be controlled. As a result, weakness in shearing strength, and brittleness peculiar to Bi may be overcomed.

Moreover, CuAlMn alloy has little toxicity, and an influence thereof on the melting point (the liquidus temperature or solidus temperature) of the bulk metal to which the alloy is added, is also small. Moreover, CuAlMn alloy has little electric resistance; thus, the CuAlMn alloy may be suitably used when an electric current is to flow through the alloy.

The content of the CuAlMn alloy in the Bi—CuAlMn is preferably from 0.5 to 20% by mass, and more preferably from 1 to 15% by mass. If the content of the CuAlMn alloy is less than 0.5% by mass, the above-mentioned advantageous effect due to add the material having martensitic transformation properties is not easily gained. If the content is more than 20% by mass, the content of Bi to be melted decreases. Therefore, the bonding strength to the bonding members easily decreases.

Even when the ratio by volume of Bi to the CuAlMn (Bi:CuAlMn) is varied from 90:10 to 45:55, the melting point (solidus temperature) of the Bi—CuAlMn is about 271° C.

In the CuAlMn alloy, it is preferable that the Mn content is from 0.01 to 20% by mass, the Al content is from 3 to 13% by mass, and the balance is composed of Cu. By adjusting this composition ratio, martensitic transformation properties are remarkably exhibited so that the bonding section composed of the solder may be prevented from being broken.

By adding Ag, Ni, Au, Sn, P, Zn, Co, Fe, B, Sb or Ge to CuAlMn alloy, the conformity with Bi is improved so that an effect of stabilizing the martensitic phase is produced. Thus, an exemplary embodiment in which the additive element(s) is/are added is also preferable.

The content of the additive element(s) in the CuAlMn alloy is preferably from 0.001 to 10% by mass. If the amount of the additive element(s) is less than 0.001% by mass, the above-mentioned effect due to add the additive element(s) is not easily gained. If the amount of the additive element(s) is more than 10% by mass, the CuAlMn alloy becomes unable to exhibit a martensitic phase.

When the particle diameter of the CuAlMn alloy particles is adjusted, stress relaxation capability of the Bi—CuAlMn or the like may be adjusted. Specifically, the particle diameter of the CuAlMn alloy particles is preferably from 0.01 to 100 μm, and more preferably from 0.01 to 20 μm.

The method for preparing the CuAlMn alloy particles is not particularly limited. A known method for preparing alloy particles may be appropriately used. An example of the preparing method will be described below; however, the method is not limited thereto.

First, Cu, Al and Mn are melted in the Ar atmosphere by means of a high-frequency induction melting furnace to form a CuAlMn alloy ingot, which is a precursor. If necessary, the additive element(s) may be added into the ingot. Next, a powder producing technique, such as atomizing, is used to make the resultant ingot into a powdery form. In this way, CuAlMn alloy particles are yielded. The CuAlMn alloy particles, which have been made into a powdery form, is plated with Ni or Au on the surfaces thereof by using a dropping method or the like. By adjusting the film thickness of the plating layers on the particle surfaces, the dispersibility of the CuAlMn alloy particles in the Bi—CuAlMn may be improved. The film thickness of the plating layers is preferably from 0.01 to 3 μm.

When the insulating part 30 is bonded to the radiator plate 40 by the Bi—CuAlMn, the bonding is performed preferably at a temperature higher several tens of centigrade degrees than the melting point (270° C.) of the Bi—CuAlMn in order to melt the bonding section uniformly and gain a sufficient fluidity. The bonding is performed preferably at about 300 to 350° C.

(3) Material in which Cu is Added to Bi

As described above, the heat resistance of the power semiconductor module may be improved even when the solder material is a pure Bi substance. However, in order to improve the brittleness of Bi, it is preferable to use a solder material in which Cu is added to Bi.

It is not completely clear why the brittleness of Bi is improved by the addition of Cu to Bi which improves mechanical strength; however, it appears that the improvement is based on the dispersion of fine Cu in Bi.

To improve the brittleness of Bi, the Cu content is preferably 0.01% by mass or more, more preferably 0.1% by mass or more, and even more preferably 0.4% by mass or more.

On the other hand, if a large amount of Cu is added, the liquidus temperature rises; thus, considering the heating temperature at the time of the bonding by the solder, the Cu content is 5% by mass or less, preferably 2% by mass or less, and even more preferably 1% by mass or less.

The relationship between the Cu content and the liquidus temperature and solidus temperature is described herein.

Upon including Cu into Bi, the liquidus temperature increases as the Cu content percentage increases. The liquidus temperature is the temperature at which all part of a solid melt and become liquid. However, even when the Cu content is greatly increased, the solidus temperature shows a substantially constant temperature of about 270° C. The solidus temperature is the temperature at which at least one part of a solid starts to melt.

In other words, as the Cu content increases, the difference between the temperature at which at least one part starts to melt (solidus temperature) and the temperature at which the melting of all parts is completed (liquidus temperature) also increases. When such a temperature difference is generated, bonding members may not bond evenly with ease upon bonding, and may be bonded together in an inclined manner, or other deficiencies may easily be generated. Further, if the liquidus temperature is high, the semiconductor element may be broken when the semiconductor element is bonded at high temperature.

When a preferable heating temperature at the time of the bonding with the solder is considered, the upper limit of the liquidus temperature of the solder material that Cu is incorporated into Bi is 650° C., and more preferably 450° C.

Specific liquidus temperatures and solidus temperatures when Cu is incorporated into Bi are shown in Table 1 described below.

TABLE 1

| Cu content in Bi | Solidus temperature | Liquidus temperature |
|---|---|---|
| (% by mass) | (° C.) | (° C.) |
| 0 | 270 | 270 |
| 0.15 | 270 | 270 |
| 0.3 | 270 | 355 |
| 0.5 | 270 | 381 |
| 0.8 | 270 | 420 |
| 1 | 270 | 470 |
| 2 | 270 | 540 |
| 5 | 270 | 650 |

The method for producing the solder material in which Cu is added to Bi is not particularly limited, and may be a known method. A specific example of the producing method is given below; however, the method is not limited thereto in the present invention.

Predetermined amounts of Bi and Cu are prepared. The components are heated and mixed with each other in a high-frequency induction melting furnace or the like, and then the mixture is cooled.

(4) Material in which Ni is Added to Bi

The brittleness of Bi is improved by adding Ni to Bi, whereby the mechanical strength increases. This reason is not completely clear; however, it appears that the improvement is based on the dispersion of fine Bi₃Ni phase in Bi.

From the viewpoint of the improvement of brittleness of Bi, the content of Ni is preferably 0.01% by mass or more, more preferably 0.1% by mass or more, and still more preferably 0.4% by mass or more.

On the other hand, if large amount of Ni is added, the liquidus temperature rises in the same manner as when Cu is added; therefore, considering the heating temperature at the time of the bonding by the solder, the Ni content is 7% by mass or less, preferably 2% by mass or less, and still more preferably 1% by mass or less.

Specific liquidus temperatures and solidus temperatures when Ni is incorporated into Bi are shown in Table 2 described below.

TABLE 2

| Ni content in Bi | Solidus temperature | Liquidus temperature |
|---|---|---|
| (% by mass) | (° C.) | (° C.) |
| 0 | 270 | 270 |
| 0.15 | 270 | 270 |
| 0.3 | 270 | 270 |
| 0.8 | 270 | 300 |
| 1 | 270 | 340 |
| 2 | 270 | 405 |
| 5 | 270 | 590 |
| 7 | 270 | 650 |

The method for producing the material in which Ni is added to Bi is not particularly limited, and may be a known method. The method may be equivalent to that for the solder material in which Cu is added to Bi.

[Faces to be Bonded by Bi Based Solder Material]

When reaction products are generated through severe thermal cyclings as in a semiconductor module, cracks are generated from the positions where this reaction products are present. When the reaction products are brittle, the reaction products may be broken to cause the generation of cracks.

Consequently, Cu layer is provided at the faces to be bonded to the members with the Bi based solder material. Specifically, in the first exemplary embodiment, the Bi based solder material is used in the second bonding section 60; therefore, the face to be bonded of each of the insulating part 30 and the radiator plate 40 has a Cu layer thereon. The possession of the Cu layer may prevent from generating an unnecessary reaction product at the interface with Bi.

As will be described later, the insulating part 30 is a Cu/SiNx/Cu laminated body, and the radiator plate 40 is preferably a Cu/Mo/Cu laminated body. Accordingly, even when the Cu layer is not provided additionally on each of the faces to be bonded by the Bi based solder material, it is sufficient that the Cu layers provided on the surfaces of the insulating part 30 and the radiator plate 40 are arranged to be set onto the interfaces with the Bi based solder material.

When no Cu/Mo/Cu laminated body is used as a radiator plate 40 so that no Cu layer is present on the surface of the radiator plate 40, a Cu layer is additionally provided on the surface of the radiator plate 40.

As the Bi based solder material, not only pure Bi substance but also a solder material in which CuAlMn alloy particles are dispersed in Bi, a solder material in which Cu is added to Bi, or a solder material in which Ni is added to Bi prevents from generating an unnecessary reaction product at the contact interfaces between the Cu layers and the bonding section, even when the added CuAlMn alloy particles, Cu or Ni contains in Bi. Thus, the durability even as a result of temperature changes also increases.

<First Bonding Section>

The first bonding section 50 in the present invention is disposed to bond between the power semiconductor element 20 and the insulating part 30. As described above, in the present invention, the material for the first bonding section 50 is not particularly limited. In the first exemplary embodiment, the Bi based solder material, which has a melting point of about 270° C., is used for the second bonding section 60; therefore, it is preferable to use a material having a sufficiently higher melting point than 270° C. for the producing process. However, in order that the power semiconductor element 20 may not be broken by heating for soldering in the producing process, it is preferable to use a material having a melting point of 450° C. or lower for the first bonding section 50.

In short, it is preferable to use a material having a melting point sufficiently higher than 270° C. and lower than 450° C. for the first bonding section 50.

The melting point of Zn is about 420° C. Since the melting point of the Bi based solder material used for the second bonding is 270° C., Zn may be used as the solder material used for the first bonding. However, considering 450° C., which is the upper limit of the more preferable range for the heating temperature upon soldering, it is desirable that the melting point is lower than this temperature.

Thus, it is preferable to add Al to Zn and prepare an alloy of Zn and Al in order to lower the melting point (solidus temperature). The alloy may contain 2% by mass or less of a metal M besides Zn and Al. In short, it is preferable to use an alloy represented by Zn_{(1-x-y)}AlₓM_{y} for the first bonding section 50.

In the alloy represented by Zn_{(1-x-y)}AlₓM_{y}, the Al content (the range of x) is preferably from 2% by mass to 10% by mass, and more preferably from 3% by mass to 8% by mass.

When Al is not contained therein (a case where x is 0), the melting point is about 420° C. as described above. As the Al content increases, the melting finish temperature (liquidus temperature) gradually drops. When the Al content is about 2% by mass, the melting finish temperature (liquidus temperature) is about 410° C. When the Al content is from about 4 to 6% by mass, the liquidus temperature is about 382° C. When the Al content is larger than about 6% by mass, the difference between the melting start temperature (solidus temperature) and the melting finish temperature (liquidus temperature) increases. When the Al content is 10% by mass, the solidus temperature is about 382° C. and the liquidus temperature is about 410° C. When the Al content is more than 10% by mass, the temperature difference between the solidus temperature and the liquidus temperature becomes larger than 30° C. Thus, the workability is declined.

The metal M in the alloy represented by Zn_{(1-x-y)}AlₓM_{y} represents a metal other than zinc and aluminum, and may include Cu or the like. When Cu is incorporated thereinto at a proportion of 2% by mass or less, the wettability becomes excellent, whereby the adhesive property is improved. Even when Cu is incorporated thereinto at a proportion of 2% by mass, the liquidus temperature hardly changes.

In the alloy represented by Zn_{(1-x-y)}AlₓM_{y}, the metal M content (the range of y) is from 0 to 2% by mass, and preferably from 0 to 1.5% by mass. If the metal M content is larger than 2% by mass, the temperature difference up to the melting completion becomes larger than 30° C., whereby the workability is declined, and when the first bonding section is bonded by the solder, deficiencies such as a misalignment or inclination of the bonded components are easily generated.

The method for preparing the alloy represented by Zn_{(1-x-y)}AlₓM_{y} is not particularly limited. A known alloy preparing method may be appropriately used.

When the power semiconductor element 20 and the insulating part 30 are bonded to each other by the alloy represented by Zn_{(1-x-y)}AlₓM_{y}, it is preferable that the bonding is performed at a temperature higher several tens of centigrade degrees than the liquidus temperature of the alloy, from the viewpoint of melting the bonding section uniformly to give a sufficient fluidity. For example, when a Zn_{(1-x-y)}AlₓM_{y} alloy having a liquidus temperature of 382° C. is used, it is preferable to perform the bonding at about 410 to 440° C.

[Faces to be Bonded by Alloy Represented by Zn_{(1-x-y)}AlₓM_{y}]

When the alloy represented by Zn_{(1-x-y)}AlₓM_{y} is used as a bonding member, it is preferable that Ni layer is provided on the faces of members to be bonded by Zn_{(1-x-y)}AlₓM_{y}.

Specifically, in the first exemplary embodiment, the alloy represented by Zn_{(1-x-y)}AlₓM_{y} is used for the first bonding section 50; thus, Ni layers 22 and 38 are provided on the faces to be bonded by Zn_{(1-x-y)}AlₓM_{y} of the power semiconductor element 20 and the insulating part 30, respectively. In the present invention, a Cu 34/SiNx 32/Cu 36 laminated body is used as the insulating part 30; therefore, Ni layer 38 is provided on Cu layer 34, which is the face to be bonded by the alloy represented by Zn_{(1-x-y)}AlₓM_{y}.

The possession of the Ni layer prevents from generating an unnecessary reaction product at the interface with the alloy represented by Zn_{(1-x-y)}AlₓM_{y}. Thus, the durability even as a result of temperature changes increases.

The thickness of the Ni layers 22 and 38 provided on the faces to be bonded by the alloy represented by Zn_{(1-x-y)}AlₓM_{y} is preferably from 0.1 to 10 μm, and more preferably from 0.5 to 5 μm. If the thickness is thinner than 0.1 μm, the Ni layers may be melted into the solder material so as to disappear when the faces are bonded. If the thickness is thicker than 10 μm, the coefficient of thermal expansion of the whole of the power semiconductor module is affected so that a thermal stress may be unfavorably generated.

The Ni layers may be formed by sputtering, plating, vapor deposition or the like.

<Power Semiconductor Element>

The power semiconductor element 20 is not particularly limited, and an appropriate element may be used in accordance with the use purpose. An conventional Si substrate (coefficient of thermal expansion: 3 ppm/° C.) or the like may be used.

In the present invention, even when a GaN substrate (coefficient of thermal expansion: 5.6 ppm/° C.), a SiC substrate (coefficient of thermal expansion: 3 ppm/° C.) or the like is used as an element for the next-generation, the present power semiconductor module becomes a highly reliable power semiconductor module such that deficiencies such as cracking and peeling are not generated even at high temperature over than 200° C., which results from heat radiated by repeated use of the semiconductor element, since the melting point (solidus temperature) of the Bi based solder material used for the second bonding section 60 is about 270° C.

In the first exemplary embodiment, the alloy represented by Zn_{(1-x-y)}AlₓM_{y} is used for the first bonding section 50; thus, the Ni layer 22 is provided on the surface of the first bonding section 50 side of the power semiconductor element 20. When the alloy represented by Zn_{(1-x-y)}AlₓM_{y} is used for the first bonding section 50, an unnecessary product is not generated at the interface between the Zn_{(1-x-y)}AlₓM_{y} layer and the Ni layer 22 through thermal cyclings. As a result, the durability even as a result of temperature changes also increases.

In order to keep anti-oxidation or wettability (adhesive property), a thin Au layer (not illustrated) may be provided on the surface of the Ni layer 22. This thin Au layer is melted into the solder bath at the time of the bonding. Thus, finally, the Au layer hardly remains in the power semiconductor module.

The thickness of the Au layer is preferably from about 0.01 to 0.5 μm, and more preferably from 0.05 μm to 0.3 μm. The Au layer may be formed by sputtering, plating, vapor deposition, or the like.

<Insulating Part>

A SiNx ceramic is used as the insulating material for the insulating part 30. In the SiNx, x represents 4/3. That is, SiNx represents Si₃N₄. However, the margin for an error of the component ratio based on a variation of the producing environment is involved.

In order to conduct electricity from the surface on the power semiconductor element side to the semiconductor element, the electroconductive layer 34 is provided on the surface of the insulating member (SiNx layer) 32. In order to prevent the module from being warped by a temperature change, the electroconductive layer 36 is also provided on the surface of the radiator plate 40 side. As the electroconductive layers 34 and 36, Cu layers are disposed. Accordingly, in the power semiconductor module of the present invention, a Cu/SiNx/Cu laminated body is used as the insulating part 30. In FIG. 1, the Cu layer, which is the electroconductive layer 34, and the power semiconductor element 20 are connected to each other by an Al wire 80.

When a Cu/AlN/Cu laminated body is used as the insulating part, it appears that an unnecessary product is not easily generated at the interface with the Bi based solder material since the laminated body has the Cu layers on its surfaces. However, the breaking strength of SiNx is 700 MPa, compared to 400 MPa of AlN. For this reason, regarding a ceramic portion, the strength of the Cu/SiNx/Cu laminated body is stronger than that of the Cu/AlN/Cu laminated body, whereby deficiencies such as cracking are not easily generated.

Furthermore, a paper by Nagatomo et al. (“Thermal Cycle Characteristic Analysis of Substrate for Power Module by Finite Element Method”, the Journal of Japan Institute of Electronics Packaging, Vol. 3, No. 4, pp. 330 to 334, 2000) reported that Cu is larger in work hardening exponent and work hardening coefficient than Al; thus a larger load is imposed on the AlN ceramic in the Cu/AlN/Cu laminated body compared to an Al/AlN/Al laminated body. In short, it is reported that the Al/AlN/Al laminated body is higher durability through thermal cyclings than the Cu/AlN/Cu laminated body.

In the meantime, in an Al/AlN/Al laminated body, irregularities of about 40 μm size may be generated under severer conditions in a thermal cycling test, specifically, through thermal cycling test in the temperature range of from −40 to 200° C.

The reason therefor has not been clear. However, it is presumed that this is based on the difference between the coefficient of thermal expansion of Al and that of AlN. The coefficient of thermal expansion of a metal plate of Al is 25 ppm/° C., and that of AlN is 4.3 ppm/° C. As described herein, between the members in the laminated body, their coefficient of thermal expansions are largely different from each other; therefore, when the Al/AlN/Al laminated body is tested in thermal cycling test at the large difference in temperature of from −40 to 200° C., a large thermal stress is repeatedly generated in the Al metal plate. Furthermore, Al has low yield stress property, whereby the plastic deformation easily undergoes. Thus, it is presumed that large irregularities are generated on the surface of Al.

Even a power semiconductor module having an insulating member such as a Cu/AlN/Cu laminated body or an Al/AlN/Al laminated body may be sufficiently put into practical use, if the temperature range in a thermal cycling test is from about −40 to 125° C.

However, in the present invention, a Cu/SiNx/Cu laminated body is used for its insulating part; therefore, deficiencies such as cracking are not easily generated even through thermal cyclings at the large difference in temperature of from −40 to 200° C.

The thickness of the electroconductive layers (Cu layers) 34 and 36 provided on the surface of SiNx is preferably from 0.01 mm to 1 mm, and more preferably from 0.05 mm to 0.6 mm. If the thickness of the electroconductive layers is less than 0.01 mm, a loss based on electric current in the transverse direction and heat generation increase. If the thickness is more than 1 mm, the coefficient of thermal expansion of the whole of the power semiconductor module is affected, whereby a thermal stress may be unfavorably generated.

The method for fixing the electroconductive layers (Cu layers) 34 and 36 onto both of the surfaces of SiNx is not particularly limited. A known method such as brazing may be appropriately adopted.

Since Cu layers are disposed as the electroconductive layers (Cu layers) 34 and 36 on the surfaces of SiNx, the Cu layers may function also as the above Cu layers disposed to prevent from generating an unnecessary reaction product at the interface with the bonding section when the Bi based solder material is used.

As described above, as the coefficient of thermal expansion difference between the Cu/SiNx/Cu laminated body as the insulating part 30 and the power semiconductor element 20 becomes smaller, the inside of the solder bonding section has less cracks. In particular, it is preferable to set the difference in coefficient of thermal expansion between the power semiconductor element 20 and the insulating part 30 (Cu/SiNx/Cu laminated body) to 1.6 ppm/° C. or less before thermal cyclings, more preferably 1.0 ppm/° C. or less. This will be described in detail hereinafter.

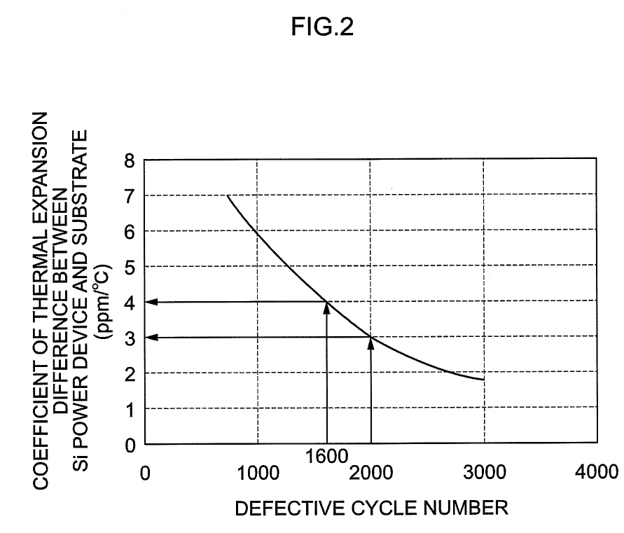

FIG. 2 is a graph showing the relationship between: the difference in coefficient of thermal expansion between the insulating part 30 and the power semiconductor element 20; and the defective cycle number.

In a test of FIG. 2, 12 mm×9 mm in size of a Si power semiconductor element (coefficient of thermal expansion: 3 ppm/° C.) was bonded to 17 mm×17 mm in size of each of substrates (insulating part) having various coefficient of thermal expansions by a Sn-0.7Cu solder material so as to set the thickness of a bonding section therebetween to 0.1 mm. In this way, each test piece was produced.

The test piece was put into a thermal cycling tester giving a temperature of −40 to 200° C. In the middle of the thermal cycling test, the test piece was taken out, and then a crack in the solder bonding section was observed by a nondestructive method by using an ultrasonic flaw detection.

As a result, it has been clear that the defective cycle number becomes smaller as the difference in coefficient of thermal expansion between the Si power semiconductor element and the substrate becomes larger, as shown in FIG. 2.

The defective cycle number means the number of thermal cyclings in which the area ratio bonded at solder bonding section becomes 90%, as shown by an equation (1) described below. The matter that this value becomes larger means that the durability is better, since the number of thermal cyclings up to the time when a defective is generated increases.

Area ratio of the solder bonding section=(the area bonded by solder after thermal cyclings/the area bonded by the solder before thermal cyclings)×100(%) Equation (1)

The reason why the number of thermal cyclings up to the time when the area of the solder bonding section becomes 90% is defined as the defective cycle number is as follows: cracking or peeling at the solder bonding section is generated from a corner of the periphery of the power semiconductor element; therefore, cracks or peels within 10% of the area ratio do not impact significantly for the heat radiation performance.

As shown in FIG. 2, when the acceptable standard of the thermal cyclings of from −40 to 200° C. is regarded as 2000 cycles, it is important that the difference in coefficient of thermal expansion is set to 3 ppm/° C. or less. In other words, since the coefficient of thermal expansion of the Si power semiconductor element is 3 ppm/° C., the coefficient of thermal expansion of the insulating part is preferably set to 6 ppm/° C. or less.

The graph in FIG. 2 shows results when Sn-0.7Cu was used as the solder material; however, the same tendency is obtained also when Bi based solder material is used.

The method for adjusting the coefficient of thermal expansion of the insulating part may include a method of changing the purity of materials used in the Cu/SiNx/Cu laminated body or the like, and preferably a method of adjusting the thickness of the Cu layers and that of the SiNx layer.

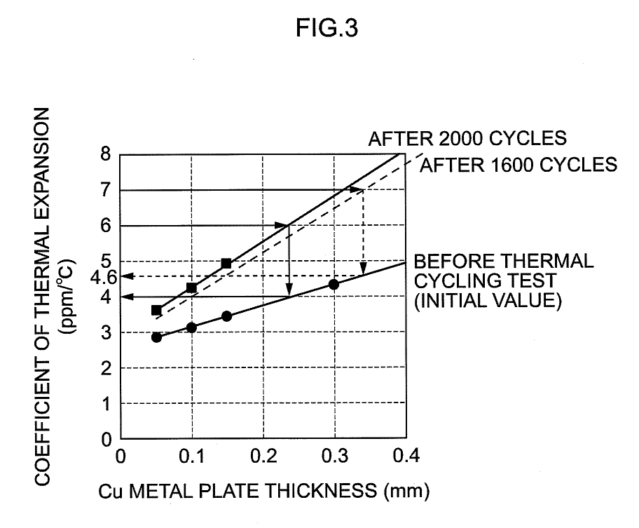

FIG. 3 shows the relationship of the coefficient of thermal expansion of the whole of the Cu/SiNx/Cu laminated body with regard to the Cu plate thickness, when Cu/SiNx/Cu laminated body was used as the insulating part 30.

The Cu/SiNx/Cu laminated body was prepared by adhering each Cu plate onto a SiNx plate, in which the SiNx plate has a plate thickness of 0.32 mm, and the Cu plates have various plate thicknesses. Cu was the so-called oxygen-free copper, which had a purity of 99.96% or more. The plate thicknesses of Cu(s) on both sides of the SiNx layer were made equal to each other.

As illustrated in FIG. 3, the coefficient of thermal expansion increases as the Cu plate thickness increases FIG. 3 also shows the coefficient of thermal expansion after thermal cyclings of from −40 to 200° C. were carried out.

In general, the coefficient of thermal expansion is a value inherent to a material; so the coefficient of thermal expansion of the insulating part should exhibit a constant value. Unexpectedly, however, as shown in FIG. 3, the coefficient of thermal expansion of the insulating part after the thermal cyclings is a higher value than the coefficient of thermal expansion before the thermal cyclings. It is therefore preferable to design the insulating part while taking into consideration the increase in the coefficient of thermal expansion of the insulating part 30 after thermal cyclings.

Specifically, when a Si power semiconductor element (coefficient of thermal expansion: 3 ppm/° C.) is used as the power semiconductor element 20, in accordance with the results in FIG. 2, it is preferable that the coefficient of thermal expansion of the insulating part 30 is set to 6 ppm/° C. or less. However, considering an increase in the insulating part 30 after a 2000-cycle test, it is more preferable to set the coefficient of thermal expansion of the insulating part 30 before the thermal cycling test to 4.0 ppm/° C. or less.

In other words, in order to set the difference between the coefficient of thermal expansion of the insulating part 30 and that of the power semiconductor element 20 to 3 ppm/° C. or less (6 ppm/° C.−3 ppm/° C.=3 ppm/° C.) after a 2000-cycle test, it is particularly preferable to set the coefficient of thermal expansion difference to 1 ppm/° C. or less (4 ppm/° C.−3 ppm/° C.=1 ppm/° C.) before the thermal cycling test.

The acceptable standard of the thermal cyclings is varied in accordance with the usage of the power semiconductor module. When the usage is a usage such that the acceptable standard of thermal cyclings of from −40 to 200° C. is 1600 cycles, according to FIG. 2 it is desirable to set the difference in coefficient of thermal expansion between the Si power semiconductor element (coefficient of thermal expansion: 3 ppm/° C.) and the insulating part 30 to 4.0 ppm/° C. or less. It is therefore preferable to set the coefficient of thermal expansion of the insulating part 30 to 7.0 ppm/° C. or less.

It may be presumed that the coefficient of thermal expansion after 1600 cycles of thermal cycling test shows dot lines in FIG. 3, from the situation of a change in the coefficient of thermal expansion between before and after 2000 cycles in the cycle test in FIG. 3.

Accordingly, in order to set the difference in coefficient of thermal expansion to 7.0 ppm or less even after 1600 cycles of thermal cycling test, it may be presumed that it is preferable to set the coefficient of thermal expansion of the insulating part 30 to 4.6 ppm or less before the thermal cycling test.

In short, if the acceptable standard of thermal cyclings of from −40 to 200° C. is decided as 1600 cycles, it is preferable to set the difference in coefficient of thermal expansion between the power semiconductor element 20 and the insulating part 30 to 1.6 ppm/° C. or less (4.6−3=1.6 ppm/° C.) before the thermal cycling test.

If the coefficient of thermal expansions of its individual members are measured before and after thermal cyclings, the results are checked, and then a power semiconductor module is produced, it is undesirable since tremendous amounts of and time and energy is required. For this reason, it is desirable and practical that it is possible to decide on the basis of the coefficient of thermal expansions before a thermal cycling test.

As described above, the coefficient of thermal expansion of a Cu/SiNx/Cu laminated body may be varied by adjusting the Cu plate thickness.

As described above, the thicknesses of the Cu layers 34 and 36 as electroconductive layers are preferably from 0.01 mm to 1 mm, and more preferably from 0.05 mm to 0.6 mm. By changing the thickness of the Cu layers and that of the SiNx layer within this thickness range of the Cu layers, the coefficient of thermal expansion of the whole of the Cu/SiNx/Cu laminated body before a thermal cycling test is adjusted. At this time, it is preferable to adjust the thicknesses so as to set the difference from the coefficient of thermal expansion of the power semiconductor element 20 to 1.6 ppm or less, and preferably 1.0 ppm/° C. or less.

The coefficient of thermal expansion of the Cu/SiNx/Cu laminated body is measured by using a TMA 8140 model manufactured by Rigaku Corp.

Specifically, the length (L) of a sample which is to have its coefficient of thermal expansion measured is first measured with a micrometer. This sample is put into the above coefficient of thermal expansion measuring device. Next, heat is applied thereto and then the elongation (length) of the sample is measured to calculate the elongation percentage ΔL per ° C. thereof. The coefficient of thermal expansion is calculated as ΔL/L (×10⁻⁶) [ppm/° C.]. It is preferable that the size of the sample is increased since measurement errors decreases accordingly; in the present case the size of the sample to be measured is from about 10 mm to 20 mm.

The Ni layer 38 is provided on the surface of the Cu layer 34 for the insulating part 30 on the side of the first bonding section 50 where the alloy represented by Zn_{(1-x-y)}AlₓM_{y} is used. As described above, the alloy represented by Zn_{(1-x-y)}AlₓM_{y} does not cause the generation of an unnecessary product at its interface with the Ni layer through thermal cyclings. Thus, by providing the Ni layer 38, deficiencies such as cracking and peeling are not easily generated even if temperature thereof changes.

The thickness of the Ni layer 38 is preferably from 0.1 μm to 10 μm, and more preferably from 3 μm to 8 μm. If the thickness is less than 0.1 μm, the layer may be melted into the solder material to disappear at the time of the bonding. If the thickness is more than 10 μm, the coefficient of thermal expansion of the whole of the power semiconductor module is affected, whereby a thermal stress may be unfavorably generated.

Furthermore, a thin Au layer (not illustrated) may be provided on the surface of the Ni layer 38 to keep anti-oxidation and the wettability. This thin Au layer is melted into the solder bath at the time of the bonding. Thus, finally, the Au layer hardly remains in the power semiconductor module.

The thickness of the Au layer is preferably from about 0.01 μm to 0.5 μm, and more preferably from 0.05 μm to 0.2 μm.

<Radiator Plate>

As the radiator plate 40, any plate having heat radiating performance may be used without particular limitation. The radiator plate is preferably a plate having sufficiently high thermoconductivity, having an excellent function as a radiator plate, and having a coefficient of thermal expansion close to that of the semiconductor element.

A specific preferable examples of the radiator plate 40 include plates composed of Mo, Cu—Mo alloy, Al—SiC, Cu, Al. Of such materials, Mo is preferable since Mo has a high thermoconductivity and a coefficient of thermal expansion close to that of the power semiconductor element.

When Mo is used for the radiator plate, other metal layers are preferably provided on both surfaces of Mo, from the viewpoint of having it possible to bond by solder. Examples of this metal layers include Cu, Ni, and preferably Cu. It is particularly preferable for the adjustment of the thermoconductivity and the coefficient of thermal expansion that the radiator plate 40 is a laminated body of a Cu layer 44/Mo layer 42/Cu layer 46, in which Cu layers are provided on surfaces of Mo.

When the radiator plate 40 is the laminated body of Cu layer 44/Mo layer 42/Cu layer 46 as described above, the ratio by thickness between the individual layers is from 1/5/1 to 1/12/1, and more preferably from 1/7/1 to 1/9/1. When the Mo layer is thicker than the thickness based on the ratio of 1/5/1, the radiator plate preferably has a coefficient of thermal expansion close to that of the power semiconductor element. When the Mo layer is thinner than the thickness based on the ratio of 1/12/1, Mo layer preferably has heat radiating function as a radiator plate.

Specifically, the layer thicknesses of the Cu layers 44 and 46 are preferably from 0.05 mm to 1 mm, and more preferably from 0.2 mm to 0.5 mm. The thickness of the Mo layer 42 is preferably from 1 mm to 7 mm, and more preferably from 2 mm to 4 mm.

Regarding the laminated body composed of the Cu layer 44/Mo layer 42/Cu layer 46, the total thickness is preferably from 1 mm to 8 mm, and more preferably from 2 mm to 5 mm in order to cause the laminated body to exhibit a heat radiating function sufficiently.

As described above, the Bi based solder material does not cause the generation of an unnecessary product at the interface with any Cu layer through thermal cyclings; thus, in the power semiconductor module according to the present invention, which has a structure in which the Cu layer 44 contacts the Bi based solder material, the durability even as a result of temperature changes also increases.

<Producing Method>

The producing method of the power semiconductor module of the present invention is not particularly limited as far as the module has the above-mentioned structure. Accordingly, a known method may be appropriately used.

In the process for producing the power semiconductor module of the first exemplary embodiment, the power semiconductor element 20 and the insulating part 30 are first bonded to each other by an alloy represented by Zn_{(1-x-y)}AlₓM_{y} to form the first bonding section 50. Thereafter, the radiator plate 40 is bonded to the insulating part 30, in which the power semiconductor element 20 is bonded at the first bonding section 50 in advance, by Bi based solder material to form the second bonding section 60.

In this producing method, in the first bonding, the alloy represented by Zn_{(1-x-y)}AlₓM_{y} is used as a solder material, and the Bi based solder material which has a lower liquidus temperature than the solidus temperature of the alloy is used for the second bonding. Thus, in the second bonding, deficiencies such as a misalignment or inclination of element 20 and section 30 are not easily caused.

Additionally, the alloy represented by Zn_{(1-x-y)}AlₓM_{y}, the solidus temperature of which is higher, is used in the first bonding section 50, which is nearer to the semiconductor element giving a large quantity of heat, while the Bi based solder material, the liquidus temperature of which is lower than that of the solder material used in the first bonding section 50, is used in the second bonding section 60, which is farther from the semiconductor element, whereby the heat resistance thereof is also excellent.

Specifically, the bonding in the first bonding section 50 between the power semiconductor element 20 and the insulating part 30 is carried out by: arranging such that the Ni layer 22 of the power semiconductor element and the Ni layer 38 of the insulating part 30 are opposed; sandwiching therebetween, an alloy represented by Zn_{(1-x-y)}AlₓM_{y}; and then performing by reflow method or the like in the atmosphere of an inert gas or a reducing gas in the state where the power semiconductor element 20 (Ni layer 38), the alloy represented by Zn_{(1-x-y)}AlₓM_{y} (first bonding member section) 50, and the insulating part 30 (Ni layer 38) are provided in this order.

The bonding temperature is preferably higher than the liquidus temperature of the alloy represented by Zn_{(1-x-y)}AlₓM_{y} by 30 to 60° C.

The thickness of the layer of the first bonding member 50 is preferably form 5 to 500 μm, and more preferably from 10 to 200 μm, from the viewpoint of heat conduction and thermal stress.

The bonding for the second bonding section 60 is carried out by using the insulating part 30, to which the power semiconductor element 20 is bonded as the first bonding section 50 in advance, and the radiator plate 40; arranging such that the Cu layer 36 of the insulating part 30 and the Cu layer 44 of the radiator plate 40 are opposed; sandwiching, therebetween, a Bi based solder material; and performing by reflow method or the like in the atmosphere of an inert gas or a reducing gas in the same manner as in the case of the bonding for the first bonding section 50, in the state where the insulating part 30 (Cu layer 36), the Bi based solder material (second bonding member region) 60, and the radiator plate 40 (Cu layer 44) are provided in this order.

The bonding temperature is preferably higher than the liquidus temperature of the Bi based solder material by about 30 to 60° C.

The wettability of Bi may not be excellent upon bonding; therefore, it is preferable to slide the members to be bonded while external pressure is applied thereto.

The thickness of the Bi based solder material is preferably from 5 to 500 μm, more preferably from 10 to 300 μm, from the viewpoint of thermal conduction and thermal stress.

<Power Semiconductor Module of a Second Exemplary Embodiment>

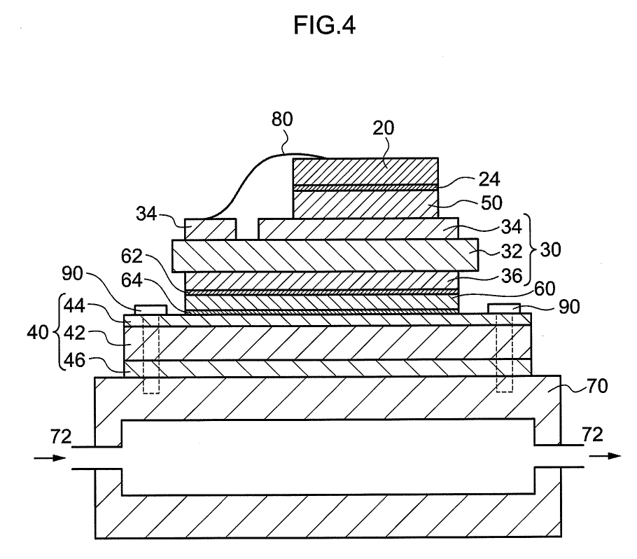

FIG. 4 shows a schematic sectional view of the structure of a power semiconductor module in a second exemplary embodiment.

In the first exemplary embodiment, the alloy represented by Zn_{(1-x-y)}AlₓM_{y} is used for the first bonding section 50 while the Bi based solder material is used for the second bonding section 60. However, in the second exemplary embodiment, a Bi based solder material is used for the first bonding section 50 while an alloy represented by Zn_{(1-x-y)}AlₓM_{y} is used for the second bonding section 60.

In the second exemplary embodiment, Cu layers are disposed on the face to be bonded of the power semiconductor element 20 and the face to be bonded of the insulating part 30 contacting with the first bonding section 50, respectively. In the present invention, however, the Cu 34/SiNx 32/Cu 36 laminated body is used as the insulating part 30; therefore, a Cu layer may not be additionally provided on the surface of the insulating part 30.

On the other hand, a Cu layer 24 is disposed on the surface of the power semiconductor element 20. The thickness of the Cu layer 24 on the surface of the power semiconductor element 20 is preferably from 0.1 to 10 μm, and more preferably from 0.5 to 5 μm. If the layer is thinner than 0.1 μm, the layer may be melted into the solder material at the time of the bonding, whereby the layer may disappear. If the layer is thicker than 10 μm, the coefficient of thermal expansion of the whole of the power semiconductor module is affected, whereby a thermal stress may unfavorably increase.

The Cu layer 24 may be formed by sputtering, plating, vapor deposition, or the like.

Ni layers 62 and 64 are provided on the face to be bonded of the insulating part 30 and the face to be bonded of the radiator plate 40 contacting the second bonding section 60, respectively. In the present invention, the Cu 34/SiNx 32/Cu 36 laminated body is used as the insulating part 30; therefore, the Ni layer 62 is provided on the surface of the Cu layer 36 on the second bonding section 60 side.

In the production of the power semiconductor module of the second exemplary embodiment, the second bonding section 60 is first bonded, and the first bonding section 50 is secondarily bonded.

The others are the same as in the first exemplary embodiment. Thus, description thereof is omitted.

<Power Semiconductor Module of Third Exemplary Embodiment>

In the third exemplary embodiment, a solder material other than any alloy represented by Zn_{(1-x-y)}AlₓM_{y} and any Bi based solder material is used for the first bonding section 50 while a Bi based solder material is used for the second bonding section 60.

However, the liquidus temperature of the solder material used in the first bonding section 50 is higher than the liquidus temperature of the Bi based solder material and lower than 650° C., more preferably lower than 450° C.

This solder materials for the first bonding section 50 include Au—Si (melting point: 360° C.), Au—Ge (melting point: 356° C.). Pb—Sn solder material may be used as the solder materials for the first bonding section 50, however, it is desirable to use a solder material without Pb, in light of a matter that a Pb-free solder material is required.

In the third exemplary embodiment, Cu layers are provided on the face to be bonded of the insulating part 30 and the face to be bonded of the radiator plate 40 contacting the second bonding section 60, respectively, in same manner as in the first exemplary embodiment.

However, the insulating part 30 is a Cu/SiNx/Cu laminated body, and the radiator plate 40 is preferably a Cu/Mo/Cu laminated body. Therefore, even when Cu layers are not additionally provided on the faces to be bonded with the Bi based solder material, it is sufficient that the interfaces with the Bi based solder material are provided with the Cu layers provided on the surfaces of the insulating part 30 and the radiator plate 40. When no Cu/Mo/Cu laminated body is used as the radiator plate 40, no Cu layers are present on the surface of the radiator plate 40, therefore a Cu layer is provided on a surface of the radiator plate 40.

Metal layers so as not to generate a reaction product by reacted with the solder material used for the first bonding section 50 may be provided or may not be provided on the face to be bonded of the power semiconductor element 20 and on the face to be bonded of the insulating part 30 contacting the first bonding section 50, respectively.

In the same manner as in the first exemplary embodiment, the first bonding section 50 is first bonded, and then the second bonding section 60 is secondarily bonded.

The others are the same as in the first exemplary embodiment. Thus, description thereof is omitted.

<Power Semiconductor Module of Fourth Exemplary Embodiment>

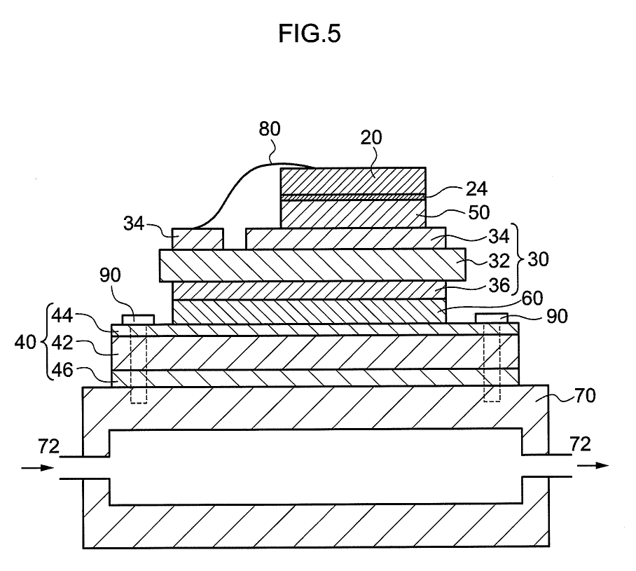

FIG. 5 shows a schematic sectional view of the structure of a power semiconductor module in a fourth exemplary embodiment.

In the first to third exemplary embodiments, different solder materials are used at the two bonding sections. However, Bi based solder materials may be used for both of the first bonding and the second bonding, when the meting point of a Bi based solder material is largely varied by changing the kind of a materials to be added to Bi or the addition amount thereof. In this case also, it is desirable that the melting point of the solder material used for the second bonding is lower than that of the solder material used for the first bonding by 30° C. or higher, and the melting point thereof is desirably 200° C. or more, considering heat generated from the power semiconductor.

In the fourth exemplary embodiment, Bi based solder materials are used at the two positions of the first and second bonding sections 50 and 60; therefore, Cu layers are provided on the faces to be bonded of the power semiconductor element 20, the insulating part 30 and the radiator plate 40, respectively. In the present invention, however, the Cu 34/SiNx 32/Cu 36 laminated body is used as the insulating part 30; thus, Cu layers may not be additionally provided on the surfaces of the insulating part 30. As the radiator plate 40, it is preferable to use the Cu layer 44/Mo layer 42/Cu layer 46; thus, Cu layers may not be additionally provided on the surfaces of the radiator plate 40.

On the other hand, a Cu layer 24 is disposed on the surface of the power semiconductor element 20. The thickness of the Cu layer 24 on the surface of the power semiconductor element 20 is preferably from 0.1 μm to 10 μm, and more preferably from 0.5 μm to 5 μm. If the layer is thinner than 0.1 μm, the layer may be melted into the solder material upon bonding, whereby the layer may disappear. If the layer is thicker than 10 μm, the coefficient of thermal expansion of the whole of the power semiconductor module is affected, whereby a thermal stress may unfavorably increase.

The Cu layer 24 may be formed by sputtering, plating, vapor deposition, or the like.

<Power Semiconductor Module of Fifth Exemplary Embodiment>

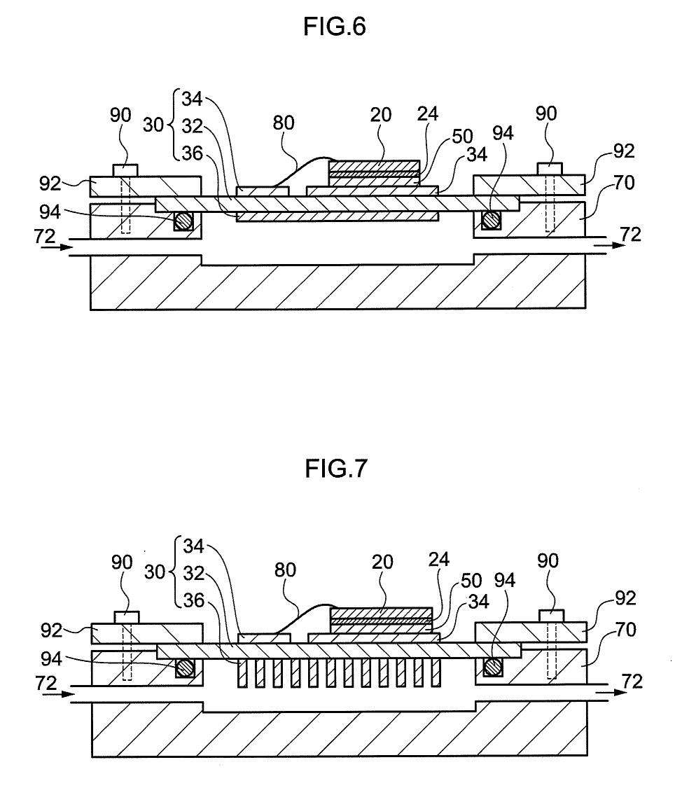

The power semiconductor module 10 of the first exemplary embodiment has the power semiconductor element 20, the insulating part 30 and the radiator plate 40. However, as shown in FIG. 6, the insulating part 30 may be directly cooled without arranging any radiator plate.

A Bi based solder material is used for the first bonding section 50, and a Cu layer 24 is provided on the face to be bonded of the power semiconductor element 20. Since the Cu 34/SiNx 32/Cu 36 laminated body is used as the insulating part 30, a Cu layer may not additionally provided on the face to be bonded of the insulating part 30.

In order to fix a cooler 70 onto the insulating part 30, the SiNx ceramic plate 32 of the insulating part 30 is sandwiched between a pushing plate 92 and the cooler 70, and fixed thereon with screws 90. At the time, an O ring is fitted into a ring-form trench made in the cooler 70 and then the pushing plate 92 is fastened across the SiNx ceramic plate 32 from the outside with the screws 90. In this way, a cooling water 72 is prevented from leaking from a gap between the cooler 70 and the ceramic plate 32.

The others are the same as in the first to fourth exemplary embodiments. Thus, description thereof is omitted.

<Power Semiconductor Module of Sixth Exemplary Embodiment>

In the power semiconductor module 10 of the fifth exemplary embodiment, the Cu layers 34 and 36 of the insulating part 30 are each in the form of a plate. As shown in FIG. 7, however, the Cu layer 36 on the cooler side may be made into a fin form.

The others are the same as in the fifth exemplary embodiment. Thus, description thereof is omitted.

### EXAMPLES

The present invention will be described by the following examples; however, the examples are concerned with an exemplary embodiment of a production method of the power semiconductor module of the present invention, and the present invention is not limited to the examples.

### Example 1

FIG. 1 shows the structure of a power semiconductor module of the present example.

<Preparation of Power Semiconductor Element>

A power semiconductor element 20 was prepared in 12 mm×9 mm in size, by using SiC (coefficient of thermal expansion: 3 ppm/° C.). A Ni layer 22 was formed on an outermost surface thereof by sputtering. An Au layer (not illustrated) was formed on the surface of the Ni layer 22 by sputtering.

<Preparation of an Insulating Part>

As an insulating part 30, a laminated body of a Cu layer 34/SiNx layer 32/Cu layer 36 was formed.

First, SiNx having 0.32 mm in thickness was prepared, and the Cu layers 34 and 36 having 0.05 mm in thickness were attached to both surfaces of this SiNx by brazing, so as to form a laminate-1.

Laminates-2, -3 and -4 were formed in the same manner, except that the thickness of the Cu layers 34 and 36 were changed to 0.1 mm, 0.15 mm or 0.3 mm, respectively. At the both surfaces of the SiNx, the thicknesses of the Cu layers were made equal to each other.

Insulating part laminates-1 to 4 were each formed by forming a Ni layer 38 on one side of the surfaces of each of the laminates-1 to 4 by plating. At the time of the plating, the surface without being plated was protected by attaching a masking sheet thereon.

The coefficient of thermal expansion of each of the resultant insulating part laminates-1 to 4 before a thermal cycling test is as shown in FIG. 3.

<Bonding at a First Bonding Section>

Electric discharge machining was used to cut a Zn_{0.96}Al_{0.04} alloy prepared in advance into a thickness of 150 to 200 μm.

The Ni layer 22 of the power semiconductor element 20 prepared as described above and the Ni layer 38 of the insulating part laminate-1 were arranged to be opposed to each other. In the state where the Zn_{0.96}Al_{0.04} as a layer 50 was sandwiched therebetween, the Ni layers was bonded each other by reflow method at bonding temperature of 420° C. in a reducing gas atmosphere. Bonding was performed at a first bonding section in this same manner, except that the insulating part laminate-1 was replaced by the insulating part laminates-2 to 4.

<Preparation of a Radiator Plate>

Cu layers were attached to both surfaces of Mo to form a laminated body composed of a Cu layer 44/Mo layer 42/Cu layer 46 as a radiator plate 40. The total thickness of the laminated body was 3 mm, and the ratio by thickness of the Cu layer 44/Mo layer 42/Cu layer 46 was 1/8/1.

<Second Bonding Section>

### (Preparation of Bi—CuAlMn)

First, an CuAlMn alloy was prepared.

An ingot of CuAlMn, which was a precursor, was obtained by melting Cu, Al and Mn, of which had been adjusted into a proportion predetermined by mass %, by using a high-frequency induction melting furnace under the atmosphere of Ar. An atomizing process was used to pulverize the resultant ingot into fine power.

The pulverized CuAlMn was plated with Ni on the surface of the powder by dropping method.

Next, the pulverized CuAlMn powder, the surface of which was plated with Ni, and Bi were put into a transparent quartz tube in a vacuum. The tube was kept at a temperature of 400° C., which is not less than the melting point of Bi, for 5 minutes. In this way, Bi was turned into a melted state, and the CuAlMn powder was evenly dispersed therein. The dispersion sample was cooled and solidified to yield Bi—CuAlMn, which was a solder material for a second bonding section 60.

Electric discharge machining was used to cut the ingot Bi—CuAlMn into a thickness of 150 to 200 μm.

(Bonding)

The Cu layer 36 of laminate-1 as an insulating part, which had been bonded to the power semiconductor element 20 at the first bonding section 50, and the Cu layer 44 of the radiator plate 40 were arranged to be opposed to each other. In the state where the Bi—CuAlMn layer, from which an oxide film had removed in advance, was sandwiched therebetween, the layers were bonded by using a reflow method at a bonding temperature of 320° C. in the atmosphere of a reducing gas to yield a power semiconductor module-1.

The resultant power semiconductor module-1 was a module in which the power semiconductor element 20, the insulating part 30 and the radiator plate 40 were laminated, and therebetween, bonded by Zn_{0.96}Al_{0.04} alloy and Bi—CuAlMn, respectively.

The bonded portions in the first bonding (the sites bonded by Zn_{0.96}Al_{0.04} alloy) were not melted even by heating during the second soldering, whereby deficiencies such as a misalignment or inclination of the bonded components were not caused.

In the same manner except that the insulating part laminate-1 was replaced by the insulating part laminates-2-4 to bond to the radiator plate, the power semiconductor modules-2 to 4 were produced.

<Thermal Cycling Test>

The resultant power semiconductor modules-1 to 4 were each tested in a thermal cycling test.

In the present example, the thermal cycling test was employed by repeating totally 2000 cycles, in which the temperature was raised and lowered between −40 and 200° C. for 20 minutes per one cycle.

Cross sections of the bonding sections after the 2000 cycles were observed with an electron microscope, and it was examined whether or not a reaction product was generated at the interfaces and deficiencies such as cracking and generating voids were generated.

As a result, a reaction product was not observed at the interfaces of the bonding sections in the power semiconductor modules-1 to 4. The states of Cu layer surfaces were not changed, and irregularities were not generated on the surfaces, either.

Accordingly, it was verified that these evaluating test bodies were highly reliable even through the thermal cyclings under the severe conditions.

### Example 2

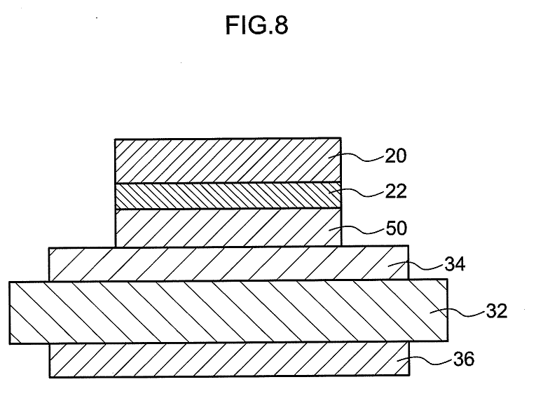

An evaluating test body-1 was produced, in which a power semiconductor element and an insulating part were bonded to each other by a Bi based solder material, as shown in FIG. 8.

<Preparation of the Power Semiconductor Element>

The power semiconductor element 20 was prepared in 12 mm×9 mm in size, by using SiC (coefficient of thermal expansion: 3 ppm/° C.). A Cu layer 22 was formed on an outermost surface thereof by sputtering.

<Preparation of the Insulating Part>

The laminate-2 (the layer thickness of the Cu layer: 0.1 mm) of the insulating part in Example 1 was prepared.

<Bonding Between Power Semiconductor Element and Insulating Part>

A pure Bi substance was cut into a thickness of 150 to 220 μm. An oxide film covering the surface of the cut pure Bi substance was removed by use of polishing and washing with an acid.

The Cu layer 22 of the power semiconductor element 20 prepared as described above and the Cu layer 34 of the insulating part 30 were arranged to be opposed to each other. In the state where the pure Bi substance layer was sandwiched therebetween, a reflow method in the atmosphere of a reducing gas of 5% H₂/N₂ was used in order to bond the Cu layers to each other at a bonding temperature of 320° C., whereby an evaluating test body-1 was obtained, in which the thicknesses of the Cu layers in the insulating part were different from each other.

<Thermal Cycling Test>

The resultant evaluating test body-1 was tested in a thermal cycling test.

In the present example, the thermal cycling test was employed by repeating 2000 cycle, in which the temperature was raised and lowered between −40 and 200° C. for 20 minutes per one cycle.

Cross sections of the bonding sections after the 2000 cycles were observed by using an electron microscope, and it was examined whether or not a reaction product was generated at the interfaces and deficiencies such as cracking and generating voids were generated.

As a result, a reaction product was not observed at the interfaces of the bonding sections in the evaluating test body-1. However, microscopic voids were slightly observed. However, no crack was generated. Additionally, the state of Cu layer surfaces were not changed, and irregularities were not generated in the surfaces, either.

Accordingly, it was verified that the evaluating test body-1 was highly reliable even through the thermal cyclings under the severe conditions.

### Example 3

An evaluating test body-2 was produced in the same manner as in Example 2, except that the pure Bi substance as a bonding material was replaced by a material in which 1% by mass of Cu was added to Bi.

The resultant evaluating test body-2 was tested in the same thermal cycling test as in Example 2. As a result, a reaction product was not observed at the interfaces of the bonding sections. Neither voids nor cracks were recognized. Accordingly, it was verified that the evaluating test body-2 was highly reliable even through the thermal cyclings under the severe conditions.

### Example 4

An evaluating test body-3 was produced in the same manner as in Example 1, except that pure Bi substance as a bonding material was replaced by a material in which 0.5% by mass of Ni was added to Bi.

The resultant evaluating test body-3 was tested in the same thermal cycling test as in Example 2. As a result, a reaction product was not observed at the interfaces of the bonding sections. Neither voids nor cracks were recognized. Accordingly, it was verified that the evaluating test body-3 was highly reliable even through the thermal cyclings under the severe conditions.

### Comparative Example 1

### Preparation of a Power Semiconductor Element

A power semiconductor element was prepared in the same manner as in the preparation of the power semiconductor element in Example 2, except that Cu layer 22 was replaced by Ni layer to form the layer on the outermost layer of the power semiconductor element 20 by sputtering.

<Preparation of Insulating Part>

An insulating part was prepared in the same way as in the preparation of the insulating part in Example 2, except that a Ni layer was formed on the surface of the Cu layer 34 in the laminate-1 by sputtering.

<Bonding at First Bonding Section>

A comparative evaluating test body-10 was produced in the same manner as in the bonding the power semiconductor element with the insulating part in Example 2, except that the Ni layer of the power semiconductor element 20 prepared as described above and the Ni layer of the insulating part 30 were arranged to be opposed to each other, and the bonding was performed in the state where a pure Bi substance was sandwiched therebetween. In the same way except this matter, a comparative evaluating test body-10 was produced.

<Thermal Cycling Test>

The resultant comparative evaluating test body-10 was tested in the same thermal cycling test as in Example 2. As a result, a large amount of Bi₃Ni was generated at the interfaces of the bonding sections, and a large number of voids were observed around the Bi₃Ni. This Bi₃Ni exhibits very brittle properties, therefore, it was verified that the body-10 did not easily gain reliability through the thermal cyclings of from −40 to 200° C.

### Comparative Example 2

A comparative evaluating test body-11 was produced. in the same manner as in Comparative Example 1, except that pure Bi substance layer was replaced by a material in which 1% by mass of Cu was added to Bi.

The resultant comparative evaluating test body-11 was tested in the same thermal cycling test as in Example 1. As a result, in the same manner as in the comparative evaluating test body-10, a large amount of Bi₃Ni was generated in the interfaces in the bonding sections, and a large number of voids were observed around the Bi₃Ni. This Bi₃Ni exhibits very brittle properties, therefore, it was verified that the body-11 did not easily gain reliability through the thermal cyclings of from −40 to 200° C.

### Comparative Example 3

A comparative evaluating test body-12 was produced in the same manner as in Comparative Example 1, except that the bonding with pure Bi substance layer was replaced by the bonding with material in which 0.5% by mass of Ni was added to Bi.

The resultant comparative evaluating test body-12 was tested in the same thermal cycling test as in Example 2. As a result, in the same manner as in the comparative evaluating test body-10, a large amount of Bi₃Ni was generated in the interfaces in the bonding sections, and a large number of voids were observed around the Bi₃Ni. This Bi₃Ni exhibits very brittle properties, therefore, it was verified that the body-12 did not easily gain reliability through the thermal cyclings of from −40 to 200° C.

### Comparative Example 4

A comparative evaluating test body-13 was produced in the same manner as in Example 3, except that the use of the Cu/SiNx/Cu laminated body as the insulating part was replaced by the use of the Al/AlN/Al laminated body.

The resultant comparative evaluating test body-13 was tested in the same thermal cycling test as in Example 1. As a result, it was recognized that irregularities of about 40 μm size were generated at the Al surfaces. Accordingly, it was verified that the body-13 did not easily gain reliability through the thermal cyclings of from −40 to 200° C.

The structures of the produced evaluating test bodies and the evaluation results thereof are together shown in Table 3 described below.

TABLE 3

| | Evaluating | Insulating | Bonding | | |
|---|---|---|---|---|---|
| | test body No. | substrate | face | Solder material | Evaluation results |
| Example 2 | 1 | Cu/SiNx/Cu | Cu layer | Pure Bi substance | Fine voids were generated but neither a |
| | | | | | reaction product nor a crack was present. |
| Example 3 | 2 | Cu/SiNx/Cu | Cu layer | 1% by mass of Cu in Bi | Not any reaction product, |
| | | | | | void or crack was present. |
| Example 4 | 3 | Cu/SiNx/Cu | Cu layer | 0.5% by mass of Ni in Bi | Not any reaction product, |
| | | | | | void or crack was present. |
| Comparative | 10 | Cu/SiNx/Cu | Ni layer | Pure Bi substance | A large amount of Bi₃Ni was generated and |
| Example 1 | | | | | a large number of voids were generated. |
| Comparative | 11 | Cu/SiNx/Cu | Ni layer | 1% by mass of Cu in Bi | A large amount of Bi₃Ni was generated and |
| Example 2 | | | | | a large number of voids were generated. |
| Comparative | 12 | Cu/SiNx/Cu | Ni layer | 0.5% by mass of Ni in Bi | A large amount of Bi₃Ni was generated and |
| Example 3 | | | | | a large number of voids were generated. |
| Comparative | 13 | Al/AlN/Al | Cu layer | 1% by mass of Cu in Bi | Irregularities of about 40 μm size were |
| Example 4 | | | | | generated at the Al surfaces. |

The whole of the disclosure of Japanese Patent Application No. 2007-108311 is incorporated by reference herein.

All publications, patent applications, and technical standards mentioned in this specification are herein incorporated by reference to the same extent as if each individual publication, patent application, or technical standard was specifically and individually indicated to be incorporated by reference.

1. A power semiconductor module comprising: a power semiconductor element having, on a surface thereof, a Cu layer; and an insulating part including a Cu/SiNx/Cu laminated body in which a SiNx ceramic plate is provided with Cu layers on both surfaces thereof,
wherein the power semiconductor element and the insulating part are arranged such that the Cu layer of the power semiconductor element and one of the Cu layers of the insulating part are opposed, and the two Cu layers are bonded to each other by a Bi based solder material.

2. A power semiconductor module comprising: a power semiconductor element; an insulating part including a Cu/SiNx/Cu laminated body in which a SiNx ceramic plate is provided with Cu layers on both surfaces thereof; and a radiator plate having a Cu layer on a surface thereof,
wherein the insulating part and the radiator plate are arranged such that one of the Cu layers of the insulating part and the Cu layer of the radiator plate are opposed, and the two Cu layers are bonded to each other by a Bi based solder material.

3. The power semiconductor module according to claim 1, wherein the difference between the coefficient of thermal expansion of the Cu/SiNx/Cu laminated body and that of the power semiconductor element is 1.6 ppm/° C. or lower before a thermal cycling test.

4. The power semiconductor module according to claim 1, wherein the purity of Cu in the Cu/SiNx/Cu laminated body is 99.96% or more.

5. The power semiconductor module according to claim 3, wherein the coefficient of thermal expansion of the Cu/SiNx/Cu laminated body is adjusted by adjusting the thicknesses of the SiNx ceramic plate and the Cu layers.

6. The power semiconductor module according to claim 1, wherein the Bi based solder material is (1) a pure Bi substance, (2) Bi—CuAlMn in which CuAlMn alloy particles are dispersed in Bi, (3) a material in which Cu is added to Bi, or (4) a material in which Ni is added to Bi.

7. The power semiconductor module according to claim 6, wherein in the material in which Ni is added to Bi, the content of Ni is from 0.01% by mass to 7% by mass.

8. The power semiconductor module according to claim 6, wherein in the material in which Cu is added to Bi, the content of Cu is from 0.01% by mass to 5% by mass.

9. The power semiconductor module according to claim 6, wherein in the Bi—CuAlMn, the content of the CuAlMn alloy particles is from 0.5% by mass to 20% by mass.

10. The power semiconductor module according to claim 2, wherein the power semiconductor element has a Ni layer on a surface thereof, the insulating part has a Ni layer on a surface thereof, the power semiconductor element and the insulating part are arranged such that the Ni layer of the power semiconductor element and the Ni layer of the insulating part are opposed, and the two Ni layers are bonded to each other by an alloy represented by Zn_{(1-x-y)}AlₓM_{y}, wherein x is from 0.02 to 0.10, y is from 0 to 0.02, and M represents a metal other than zinc and aluminum.

11. The power semiconductor module according to claim 1, wherein the power semiconductor element comprises GaN or SiC.

12. The power semiconductor module according to claim 2, wherein the radiator plate is a laminated body including a Cu layer/Mo layer/Cu layer in which a Mo layer is provided with Cu layers on both surfaces thereof.

13. The power semiconductor module according to claim 12, wherein the ratio by thickness in the radiator plate between the Cu layer, the Mo layer, and the Cu layer is from 1/5/1 to 1/12/1.
